(19) United States
(12) Patent Application Publication
(10) Pub. No.: US 2026/0040667 A1
(43) Pub. Date: Feb. 5, 2026

(54) SEMICONDUCTOR DEVICE

(71) Applicant: Samsung Electronics Co., Ltd., Suwon-si (KR)

(72) Inventors: Seunggeun Jung, Suwon-si (KR); Myunggil Kang, Suwon-si (KR); Dongwon Kim, Suwon-si (KR); Seokhoon Kim, Suwon-si (KR); Beomjin Park, Suwon-si (KR); Pankwi Park, Suwon-si (KR)

(21) Appl. No.: 19/170,120

(22) Filed: Apr. 4, 2025

(30) Foreign Application Priority Data
Aug. 5, 2024 (KR) 10-2024-0103726

(51) Int. Cl. H10D 84/83; H10D 30/00; H10D 30/01; H10D 62/10; H10D 62/13; H10D 62/40; H10D 62/60; H10D 62/834; H10D 64/23; H10D 84/01

(52) U.S. Cl. CPC H10D 84/832; H10D 30/503; H10D 62/121; H10D 62/151; H10D 62/405; H10D 62/60; H10D 62/834; H10D 64/256; H10D 84/8312; H10D 30/019; H10D 84/013; H10D 84/0149

(57) ABSTRACT

A semiconductor device includes a substrate having first and second regions; first and second channel layers on the first region and the second region with a first gate electrode and a second gate electrode thereon, respectively; a first source/drain region and a second source/drain region on at least one side of the first gate electrode and the second gate electrode, respectively; an auxiliary epitaxial pattern extending into the second source/drain region from an upper surface thereof, a first contact plug extending into the first source/drain region from an upper surface thereof; and a second contact plug extending into the auxiliary epitaxial pattern from an upper surface thereof. The first source/drain region has a first depth and a first impurity region including first impurities, the second source/drain region has a second depth and a second impurity region including second impurities, with the second depth greater than the first depth.

### CROSS-REFERENCE TO RELATED APPLICATION(S)

This application claims benefit of priority to Korean Patent Application No. 10-2024-0103726 filed on Aug. 5, 2024, in the Korean Intellectual Property Office, the disclosure of which is incorporated herein by reference in its entirety.

### TECHNICAL FIELD

The present inventive concept relates to a semiconductor device, and more specifically, to a three-dimensional semiconductor device including a field effect transistor.

### BACKGROUND

As demand for high performance, high speed and/or multifunctionality in semiconductor devices increases, integration of the semiconductor devices is increasing. In manufacturing a semiconductor device with a fine pattern corresponding to a trend of high integration of semiconductor devices, it may be required to implement patterns having a fine width or a fine gap distance. In addition, efforts are being made to develop a semiconductor device including a FinFET having a three-dimensional channel, in order to address limitations on operating characteristics due to a size reduction of a planar MOSFET (metal oxide semiconductor field effect transistor).

### SUMMARY

Some embodiments of the present inventive concept provide a semiconductor device with improved electrical characteristics.

However, the inventive concept are not limited to the mentioned object, and can be variously extended without departing from the spirit and scope of the present inventive concept.

According to an aspect of the present inventive concept, a semiconductor device may comprise: a substrate having a first region and a second region; a first gate electrode extending on the first region in a first direction; a second gate electrode extending on the second region in the first direction; a plurality of channel layers spaced apart from each other in a second direction perpendicular to an upper surface of the substrate, the plurality of channel layers including first channel layers and second channel layers on the first region and the second region with the first gate electrode and the second gate electrode thereon, respectively; a first source/drain region connected to the first channel layers on at least one side of the first gate electrode; a second source/drain region connected to the second channel layers on at least one side of the second gate electrode; an auxiliary epitaxial pattern extending into the second source/drain region from an upper surface thereof and electrically connected to the second source/drain region; a first contact plug extending into the first source/drain region from an upper surface of the first source/drain region; and a second contact plug extending into the auxiliary epitaxial pattern from an upper surface of the auxiliary epitaxial pattern. The first source/drain region has a first depth in the second direction from the upper surface of the first source/drain region and comprises a first impurity region including first impurities of a first conductivity type, and the second source/drain region has a second depth in the second direction from the upper surface of the second source/drain region and comprises a second impurity region including second impurities of a second conductivity type that is different from the first conductivity type, with the second depth being greater than the first depth.

According to an aspect of the present inventive concept, a semiconductor device may comprise: a substrate comprising an active region extending in a first direction; a gate structure extending in a second direction intersecting the active region on the substrate; a plurality of channel layers on the active region and spaced apart from each other in a third direction, which is perpendicular to an upper surface of the substrate, with the gate structure thereon; a source/drain region in a recessed region of the active region on at least one side of the gate structure and connected to the plurality of channel layers, where the source/drain region comprises a first epitaxial layer on the active region and in contact with the plurality of channel layers, and a second epitaxial layer on the first epitaxial layer, an upper surface of the second epitaxial layer comprising a first portion and a second portion having a cavity therein that extends toward the active region, the first portion extending around the cavity; an auxiliary epitaxial pattern in the cavity of the second epitaxial layer and having a surface defined by a crystal plane; a metal-semiconductor compound layer extending into an upper surface of the auxiliary epitaxial pattern, electrically connected to the source/drain region, and extending along a recessed surface of the auxiliary epitaxial pattern; and a contact plug comprising a contact conductive layer on the metal-semiconductor compound layer, and extending in the third direction.

According to an aspect of the present inventive concept, a semiconductor device may comprise: a substrate having a first region and a second region; a first gate electrode extending on the first region in a first direction; a second gate electrode extending on the second region in the first direction; a plurality of channel layers spaced apart from each other in a second direction perpendicular to an upper surface of the substrate, the channel layers comprising first channel layers and second channel layers on the first region and the second region and with the first gate electrode and the second gate electrode thereon, respectively; a first source/drain region connected to the first channel layers on at least one side of the first gate electrode; a second source/drain region connected to the second channel layers on at least one side of the second gate electrode; an auxiliary epitaxial pattern extending into the second source/drain region from an upper surface thereof and electrically connected to the second source/drain region; a first contact plug extending into the first source/drain region from an upper surface of the first source/drain region; and a second contact plug extending into the auxiliary epitaxial pattern from an upper surface of the auxiliary epitaxial pattern. Each of the first source/drain region and the second source/drain region comprises: a first epitaxial layer on side surfaces of the plurality of channel layers and having a first impurity concentration; and a second epitaxial layer on the first epitaxial layer and having a second impurity concentration, greater than the first impurity concentration. The semiconductor device further comprises: a first metal-semiconductor compound layer extending into an upper surface of the second epitaxial layer in the first source/drain region and being in contact with the second epitaxial layer of the first source/drain region and the first contact plug; and a second metal-semiconductor compound layer extending into the upper surface of the auxiliary epitaxial pattern and being in contact with the auxiliary epitaxial pattern and the second contact plug.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view illustrating a semiconductor device according to embodiments of the present inventive concept;

FIG. 2A is cross-sectional views illustrating an embodiment of the semiconductor device illustrated in FIG. 1 along lines I-I′ and II-II′;

FIG. 2B is a cross-sectional view illustrating an embodiment of the semiconductor device illustrated in FIG. 1 along lines III-III′;

FIG. 3 is an enlarged view illustrating an embodiment of region A of the semiconductor device illustrated in FIG. 2A;

FIG. 4 is an enlarged view showing an embodiment of region B of the semiconductor device illustrated in FIG. 2A;

FIGS. 5 and 6 are enlarged views illustrating another embodiments of region B of the semiconductor device illustrated in FIG. 2A;

FIG. 7 is a plan view illustrating a semiconductor device according to another embodiment of the present inventive concept;

FIGS. 8A, 8B, and 8C are cross-sectional views illustrating embodiments of the semiconductor device illustrated in FIG. 7 along lines IV-IV′ and V-V′;

FIGS. 9A, 9B, 9C, 9D, 9E, 9F, 9G, and 9H are cross-sectional views illustrating an embodiment of a method for manufacturing the semiconductor device in FIG. 2A; and

FIGS. 10A, 10B, and 10C are cross-sectional views illustrating an embodiment of a method for manufacturing the semiconductor device in FIG. 5.

### DETAILED DESCRIPTION OF EMBODIMENTS

Hereinafter, example embodiments of the present inventive concept will be described with reference to the accompanying drawings. The same reference numerals are used for the same components in the drawings, and duplicate descriptions for the same components are omitted. The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Spatially relative terms such as “above,” “upper,” “below,” “lower,” “side,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features.

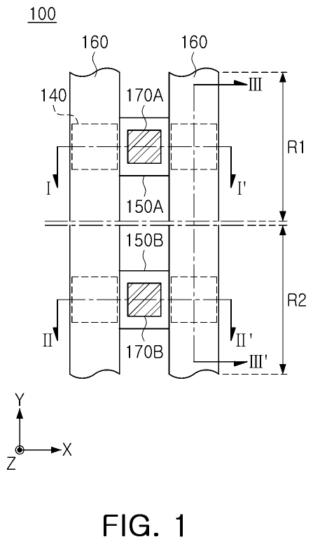

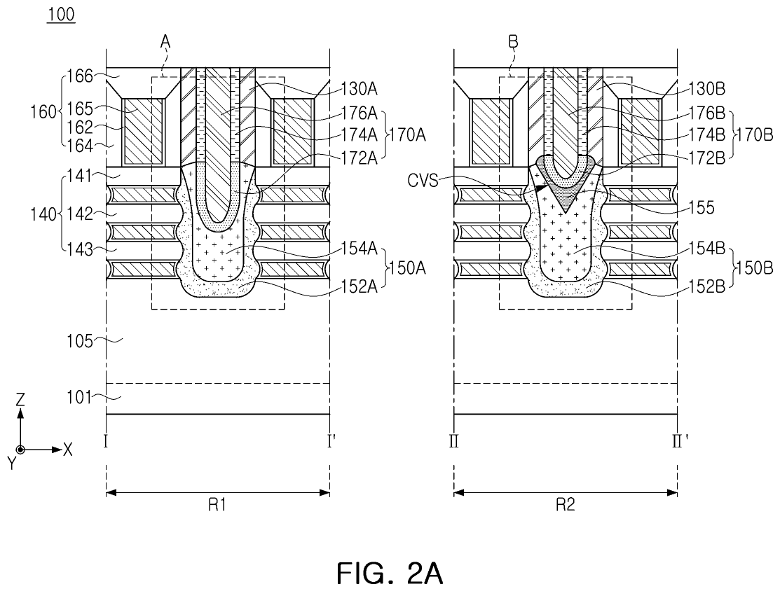

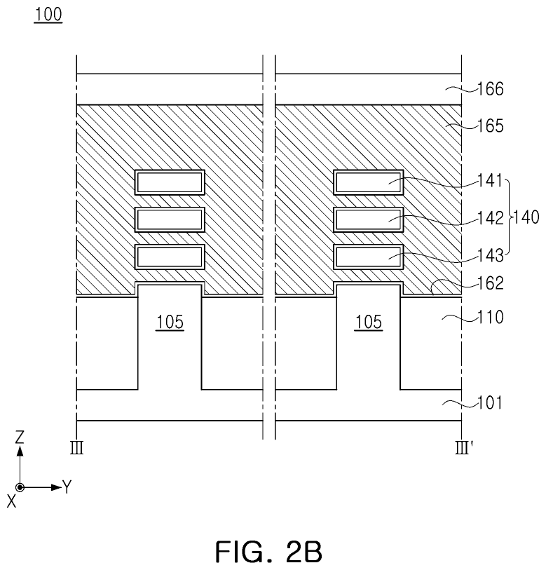

FIG. 1 is a plan view illustrating a semiconductor device according to embodiments of the present inventive concept. FIG. 2A is cross-sectional views illustrating an embodiment of the semiconductor device illustrated in FIG. 1 along lines I-I′ and II-II′. FIG. 2B is a cross-sectional view illustrating an embodiment of the semiconductor device illustrated in FIG. 1 along lines III-III′. For convenience of explanation, only some components of the semiconductor device are illustrated in FIG. 1.

Referring to FIGS. 1, 2A and 2B, the semiconductor device 100 may include a substrate 101 having first and second regions R1 and R2, an active region 105 on the substrate 101, device isolation layers 110 defining the active region 105, channel structures 140 including first to third channel layers 141, 142 and 143 vertically spaced apart from each other (e.g., in the Z-direction) on the active region 105, a gate structure 160 extending intersecting the active region 105, first and second source/drain regions 150A and 150B in contact with the channel structures 140, a first contact plug 170A connected to the first source/drain region 150A, a second contact plug 170B connected to the second source/drain region 150B, first and second insulating liners 130A and 130B disposed between the gate structure 160 and the first and second contact plugs 170A and 170B, and an auxiliary epitaxial pattern 155 disposed between the second source/drain region 150B and the second contact plug 170B.

The substrate 101 may have an upper surface extending in a first direction (X-direction) and a second direction (Y-direction). The substrate 101 may include a semiconductor material, such as a group IV semiconductor, a group III-V compound semiconductor or a group II-VI compound semiconductor. For example, the group IV semiconductor may include silicon, germanium or silicon-germanium. The substrate 101 may be provided as a bulk wafer, an epitaxial layer, a Silicon On Insulator (SOI) layer, or a Semiconductor On Insulator (SeOI) layer.

The device isolation layer 110 may define the active region 105 in the substrate 101. The device isolation layer 110 may be formed, for example, by a shallow trench isolation (STI) process. Depending on embodiments, the device isolation layer 110 may further include a region extending deeper and having a step to a lower portion of the substrate 101. The device isolation layer 110 may partially expose an upper portion of the active region 105. The term “expose” may be used to describe relationships between elements and/or certain intermediate processes in fabricating a completed semiconductor device, but may not necessarily require exposure of the particular region, layer, structure or other element in the context of the completed device. Depending on embodiments, the device isolation layer 110 may have a curved upper surface having a higher level as it approaches the active region 105. The term “level” may be used herein to describe a distance of an element or surface from a reference element or surface (such as the substrate 101) in a direction perpendicular to the reference element or surface. The device isolation layer 110 may be made of an insulating material. The isolation layer 110 may be, for example, an oxide, a nitride, or a combination thereof.

The active region 105 may be defined by the device isolation layer 110 in the substrate 101 and may be disposed to extend in the first direction (X-direction). The active region 105 may have a structure protruding from the substrate 101. A top of the active region 105 may be disposed to protrude from the upper surface of the device isolation layer 110 by a predetermined height. The active region 105 may be formed as a portion of the substrate 101, or may include an epitaxial layer grown from the substrate 101. However, on both (e.g., opposing) sides of the gate structure 160, the active region 105 on the substrate 101 may be partially recessed, and the first and second source/drain regions 150A and 150B may be disposed on the recessed portions of the active region 105. The active region 105 may include impurities or include doped regions including impurities.

The substrate 101 may include first and second regions R1 and R2, and the first and second regions R1 and R2 may be adjacent or spaced apart from each other. The first source/drain region 150A and the first contact plug 170A may be disposed in the first region R1, and the second source/drain region 150B and the second contact plug 170B may be disposed in the second region R2. For example, the first region R1 may be an nFET region, and the second region R2 may be a pFET region. However, in some embodiments, the first and second regions R1 and R2 may be regions in which transistors having the same conductivity type but different electrical characteristics are disposed. The first and second regions R1 and R2 may be referred to as regions of the semiconductor device 100, not as regions of the device isolation layer 110. The gate structures 160 may be disposed on the active region 105 and the channel structures 140 to extend in the second direction (Y-direction) while intersecting the active region 105 and the channel structures 140. A channel region of the transistors may be formed in the channel structure 140 intersecting a gate electrode 165. The channel region of the transistors may be formed in the active region 105 and the channel structures 140 intersecting the gate structure 160. The gate structures 160 may be spaced apart from each other in the first direction (X-direction). Each of the gate structures 160 may include gate dielectric layers 162, gate spacer layers 164, the gate electrode 165 and a gate capping layer 166. In this specification, the gate structures 160 arranged in the first region R1 may be referred to as the first gate structure, and the gate structures 160 arranged in the second region R2 may be referred to as the second gate structure.

The gate dielectric layers 162 may be disposed between the device isolation layer 110 and the gate electrode 165 and between the channel structure 140 and the gate electrode 165, and may be disposed to cover at least a portion of surfaces of the gate electrode 165. For example, the gate dielectric layers 162 may extend between the gate electrode 165 and the gate spacer layers 164, but are not limited thereto. The terms “cover” or “surround” or “fill” as may be used herein may not require completely covering or surrounding or filling the described elements or layers, but may, for example, refer to partially covering or surrounding or filling the described elements or layers, for example, with voids or other discontinuities therein. The gate dielectric layers 162 may include an oxide, a nitride or a high-K material. The high-material may mean a dielectric material having a dielectric constant higher than that of silicon oxide (SiO₂). The high-K material may be, for example, at least one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}) or praseodymium oxide (Pr₂O₃). Depending on embodiments, the gate dielectric layer 162 may be formed in a multilayer structure.

The gate electrode 165 may include a conductive material, for example, a metal nitride such as titanium nitride (TiN), tantalum nitride (TaN) or tungsten nitride (WN), and/or a metal material such as aluminum (Al), tungsten (W) or molybdenum (Mo), or a semiconductor material such as doped polysilicon. Depending on embodiments, the gate electrode 165 may be formed of a multilayer structure. In a region not shown, the gate electrodes 165 may be connected to gate contact plugs disposed thereon.

The gate spacer layers 164 may be disposed on both (e.g., opposing) side surfaces of the gate electrode 165 on the channel structures 140. The gate spacer layers 164 may insulate the first and second source/drain regions 150A and 150B from the gate electrodes 165. Depending on embodiments, shapes of tops of the gate spacer layers 164 may be variously changed, and the gate spacer layers 164 may be formed of a multilayer structure. The gate spacer layers 164 may include at least one of an oxide, a nitride or an oxynitride, and may be formed of, for example, a low-K film.

The gate capping layer 166 may be disposed on the gate electrode 165, and may be disposed between the gate spacer layers 164. In another embodiment, a lower surface of the gate capping layer 166 may have a convex shape facing downward. The gate capping layer 166 may include an insulating material, and may include, for example, at least one of an oxide, a nitride or an oxynitride.

The channel structure 140 may include two or more plurality of channel layers, for example, first, second and third channel layers 141, 142 and 143, spaced apart from each other 105 on the active region 105 in the third direction (Z-direction) perpendicular to an upper surface of the active region 105. The first, second and third channel layers 141, 142 and 143 may be sequentially disposed from an upper side. The channel structures 140 may be spaced apart from the upper surface of the active region 105 while being connected to the first and second source/drain regions 150A and 150B. The channel structures 140 may have a width equal or similar to that of the gate structure 160 in the first direction (X-direction). In a cross section along the second direction (Y-direction), the channel layer disposed at a lower side among the first, second, and third channel layers 141, 142 and 143 may have a width equal to or greater than that of the channel layer disposed at an upper side. In another embodiment, the channel structures 140 may have a reduced width compared to the gate structures 160 so that side surfaces thereof can be located below the gate structures 160 in the first direction (X-direction).

The channel structures 140 may be made of a semiconductor material, and may include, for example, at least one of silicon (Si), silicon germanium (SiGe) or germanium (Ge). The number and shape of the channel layers forming one channel structure 140 may vary in embodiments.

In the semiconductor device 100, the gate electrode 165 may be disposed between the first, second and third channel layers 141, 142 and 143 of the channel structures 140 and on the channel structures 140. Accordingly, a transistor having a MBCFET™ (Multi Bridge Channel FET) structure, which is a gate-all-around (GAA) type field effect transistor, may be included.

The first and second source/drain regions 150A and 150B may be disposed to be in contact with the channel structures 140 on both (e.g., opposing) sides of the gate structures 160. The first and second source/drain regions 150A and 150B may be disposed to cover side surfaces of the first, second and third channel layers 141, 142 and 143 of the channel structure 140 in the first direction (X-direction). The first source/drain region 150A may be connected to the first contact plug 170A through an upper surface or top thereof, and the second source/drain region 150B may be connected to the second contact plug 170B disposed on an upper surface or top of the auxiliary epitaxial pattern 155.

The first source/drain region 150A may have a shape recessed by the first contact plug 170A, and the second source/drain region 150B may have a shape recessed by the auxiliary epitaxial pattern 155. Upper surfaces of the first and second source/drain regions 150A and 150B may be disposed on a level equal to or higher than a lower surface of the gate electrode 165 on the channel structure 140 relative to the substrate 101.

Each of the first source/drain region 150A and the second source/drain region 150B may include a first epitaxial layer 152A and 152B and a second epitaxial layer 154A and 154B. In an example, the first source/drain region 150A may include a first epitaxial layer 152A and a second epitaxial layer 154A on the first epitaxial layer 152A. The second source/drain region 150B may include a first epitaxial layer 152B and a second epitaxial layer 154B on the first epitaxial layer 152B.

The first epitaxial layer 152A and 152B may cover side surfaces of each of the first, second, and third channel layers 141, 142 and 143 along the first direction (X-direction), and may cover side surfaces of the gate structures 160 below the channel structure 140 along the first direction (X-direction). The first epitaxial layers 152A and 152B may extend to cover inner walls and bottom surfaces of the recessed regions in which the first and second source/drain regions 150A and 150B are disposed, respectively. The first epitaxial layer 152A and 152B may have an outer surface that protrudes convexly toward the gate structure 160 from below the first, second, and third channel layers 141, 142 and 143, and thus may have a curved outer surface. However, a shape of the first epitaxial layer 152A and 152B is not limited to the shape illustrated in FIG. 2A.

The second epitaxial layer 154A and 154B may cover the first epitaxial layer 152A and 152B and fill the recessed region. A width of the second epitaxial layer 154A and 154B in the first direction (X-direction) may be greater than a thicknesses on one side of the channel structure 140 of the first epitaxial layer 152A and 152B. In another embodiment, each of the first and second source/drain regions 150A and 150B may further include a third epitaxial layer on an upper surface of the second epitaxial layer 154A and 154B.

The first and second source/drain regions 150A and 150B may include a semiconductor material, such as at least one of silicon (Si) or germanium (Ge), and may further include impurities. The first epitaxial layer 152A and 152B and the second epitaxial layer 154A and 154B may have different compositions. A concentration of a non-silicon element in the second epitaxial layers 154A and 154B may be greater than a concentration of a non-silicon element in the first epitaxial layer 152A and 152B. The non-silicon element may be, for example, germanium (Ge) and/or a doping element. In an example, when the first region R1 is an nFET region and the second region R2 is a pFET region, the first source/drain region 150A may not include germanium (Ge) or may include germanium (Ge) at a concentration less than that of the second source/drain region 150B. For example, the first source/drain region 150A may include silicon (Si) and the second source/drain region 150B may include silicon germanium (SiGe). A concentration of germanium (Ge) of the first epitaxial layer 152B may be less than a concentration of germanium (Ge) of the second epitaxial layer 154B.

The second epitaxial layer 154A and 154B may have a doping concentration of a doping element, i.e., impurities, greater than that of the first epitaxial layer 152A and 152B. Accordingly, a resistivity of the second epitaxial layer 154A and 154B may be less than a resistivity of the first epitaxial layer 152A and 152B. For example, the impurities of the first source/drain region 150A may be N-type impurities such as at least one of phosphorus (P), arsenic (As) and antimony (Sb), and the impurities of the second source/drain region 150B may be P-type impurities such as at least one of boron (B), gallium (Ga), and indium (In). For example, the concentration of the impurities of the first epitaxial layer 152A and 152B may be in a range of about 1×10²⁰/cm³ to about 6×10²¹/cm³, and the concentration of the impurities of the second epitaxial layer 154A or 154B may be in a range of about 1×10²¹/cm³ to about 1×10²²/cm³, but the present inventive concept is not limited thereto.

The first contact plug 170A may extend in the vertical third direction (Z-direction) to be connected to the first source/drain region 150A, and may apply an electrical signal to the first source/drain region 150A. The first contact plug 170A is illustrated as having a constant width along the third direction (Z-direction), but the present inventive concept is not limited thereto, and in another example, the first contact plug 170A may have an inclined side surface in which a width of a lower portion thereof is narrower than a width of an upper portion thereof depending on an aspect ratio. The first contact plug 170A may be recessed from (i.e., may extend into a recess in) the upper surface of the first source/drain region 150A toward the substrate 101. The first contact plug 170A may be recessed from or extend into the upper surface of the second epitaxial layer 154A toward the device isolation layer 110.

The second epitaxial layer 154A of the first source/drain region 150A may include an inner surface in contact with the first epitaxial layer 152A and an outer surface formed concavely toward the substrate 101 and having a recessed surface in contact with the first contact plug 170A. In an example, the outer surface of the second epitaxial layer 154A may include a first portion disposed on a level equal to or higher than a lower surface of the gate structure 160 and a second portion having a lower surface extending to the first portion and disposed on a level lower than the lower surface of the gate structure 160. A lower portion of the first contact plug 170A may be surrounded by the second portion of the second epitaxial layer 154A.

A first contact plug 170A may include a first conductive layer 176A, a first metal-semiconductor compound layer 172A positioned between the first conductive layer 176A and a first source/drain region 150A, and a first conductive liner 174A surrounding a side surface of the first conductive layer 176A. The first metal-semiconductor compound layer 172A may be in contact with the first source/drain region 150A. The first metal-semiconductor compound layer 172A may be in contact with an outer surface and/or an inner surface of a second epitaxial layer 154A of the first source/drain region 150A. The first conductive liner 174A may extend from the first metal-semiconductor compound layer 172A, and may not be in contact with the first source/drain region 150A. The first conductive layer 176A in contact with the first metal-semiconductor compound layer 172A may correspond to a surface profile of the first metal-semiconductor compound layer 172A. In an example, a lower surface of the first conductive layer 176A may have a shape protruding toward the substrate 101.

The first metal-semiconductor compound layer 172A may include a metal silicide layer, such as titanium silicide (TiSi) or molybdenum silicide (MoSi), and the first conductive layer 176A may include a metal material, such as tungsten (W), molybdenum (Mo) or aluminum (Al). The first conductive liner 174A may be a barrier film of the first conductive layer 176A, and may surround a side surface of the first conductive layer 176A on the first source/drain region 150A. The first conductive liner 174A may extend from the first metal-semiconductor compound layer 172A. The first conductive liner 174A may include titanium (Ti), titanium nitride (TiN), tantalum nitride (TaN) and/or tungsten nitride (WN). In another example, the first conductive liner 174A may include a plurality of barrier films. For example, the first conductive liner 174A may include a first barrier film surrounding the side surface of the first conductive layer 176A and a second barrier film surrounding the first barrier film. The first barrier film may include titanium nitride (TiN), and the second barrier film may include titanium (Ti).

The second epitaxial layer 154B of the second source/drain region 150B may include an inner surface in contact with the first epitaxial layer 152B and an outer surface including a recess or cavity CVS recessed toward the substrate 101 and having inclined surfaces. In an example, the inclined surfaces of the cavity CVS of the second epitaxial layer 154B may be a surface from which the auxiliary epitaxial pattern 155 is grown. For example, each of inclined surfaces of the cavity CVS of the second epitaxial layer 154B may be an inclined surface having a (1 1 1) crystal plane. The cavity may have a tip where the (1 1 1) crystal planes meet.

The outer surface of the second epitaxial layer 154B may include a first portion disposed at a level equal to or higher than the lower surface of the gate structure 160 and a second portion extending to the first portion, wherein the cavity CVS is disposed in the second portion. The second portion of the second epitaxial layer 154B may be surrounded by the first portion of the second epitaxial layer 154B.

The auxiliary epitaxial pattern 155 may be accommodated in the cavity CVS of the second epitaxial layer 154B. The auxiliary epitaxial pattern 155 may be an epitaxial pattern grown from the inclined surface of the cavity CVS of the second epitaxial layer 154B.

The auxiliary epitaxial pattern 155 may include a semiconductor material such as at least one of silicon (Si) or germanium (Ge), and a concentration of a non-silicon element of the auxiliary epitaxial pattern 155 may be greater than a concentration of a non-silicon element of the second epitaxial layer 154B.

A lower surface (or inner surface) of the auxiliary epitaxial pattern 155 in contact with the second epitaxial layer 154B may have a shape corresponding to a shape of the cavity CVS of the second epitaxial layer 154B. The lower surface of the auxiliary epitaxial pattern 155 may have an inclined surface. A bottom of the auxiliary epitaxial pattern 155 may refer to the lowest level or lowermost portion that is in contact with the second epitaxial layer 154B of the second source/drain region 150B among the lower surfaces of the auxiliary epitaxial pattern 155. In an example, an upper surface of the auxiliary epitaxial pattern 155 may be disposed on a level higher than an upper surface of the first portion of the second epitaxial layer 154B. That is, the upper surface of the auxiliary epitaxial pattern 155 may have a convex surface protruding in the vertical third direction (Z-direction). An inner curved surface that is penetrated or recessed by the second contact plug 170B may be formed on the convex surface of the auxiliary epitaxial pattern 155. The convex surface of the auxiliary epitaxial pattern 155 may be in contact with the second insulating liner 130B.

The second contact plug 170B may extend in the vertical third direction (Z-direction) to be connected to the second source/drain region 150B through the upper surface or a top of the auxiliary epitaxial pattern 155, and may apply an electrical signal to the second source/drain region 150B. The second contact plug 170B is illustrated as having a constant width in the third direction (Z-direction), but the present inventive concept is not limited thereto, and in another example, the second contact plug 170B may have an inclined side surface in which a width of a lower portion thereof is narrower than a width of an upper portion thereof depending on an aspect ratio. The second contact plug 170B may be recessed from (i.e., may extend into a recess in) the upper surface of the auxiliary epitaxial pattern 155 toward the device isolation layer 110.

A lower portion of the second contact plug 170B may be surrounded by the auxiliary epitaxial pattern 155. The second contact plug 170B may include a second conductive layer 176B, a second metal-semiconductor compound layer 172B positioned between the second conductive layer 176B and the auxiliary epitaxial pattern 155, and a second conductive liner 174B surrounding a side surface of the second conductive layer 176B. The second metal-semiconductor compound layer 172B may be in contact with an outer surface and/or an inner surface of the auxiliary epitaxial pattern 155. The second conductive liner 174B may extend from the second metal-semiconductor compound layer 172B and surround a side surface of the second conductive layer 176B. The second conductive liner 174B may not be in contact with the auxiliary epitaxial pattern 155. The second conductive layer 176B in contact with the second metal-semiconductor compound layer 172B may correspond to a surface profile of the second metal-semiconductor compound layer 172B. A lower surface of the second conductive layer 176B may have a convex shape toward the substrate 101.

The second metal-semiconductor compound layer 172B may include a metal silicide layer, such as titanium silicide (TiSi) or molybdenum silicide (MoSi), and the second conductive layer 176B may include a metal material, such as tungsten (W), molybdenum (Mo) or aluminum (Al). The second conductive liner 174B may surround the side surface of the second conductive layer 176B as a barrier film of the second conductive layer 176B. The second conductive liner 174B may extend from the second metal-semiconductor compound layer 172B. The second conductive liner 174B may include titanium (Ti), titanium nitride (TiN), tantalum nitride (TaN), and/or tungsten nitride (WN).

In another example, the second conductive liner 174B may include a plurality of barrier films. For example, the second conductive liner 174B may include a first barrier film surrounding the side surface of the second conductive layer 176B and a second barrier film surrounding the first barrier film. For example, the first barrier film may include titanium nitride (TiN), and the second barrier film may include titanium (Ti).

The first contact plug 170A may recess or extend into the first source/drain region 150A to a first depth. The second contact plug 170B may recess or extend into the auxiliary epitaxial pattern 155 to a second depth different from the first depth. For example, the first depth may be greater than the second depth. A lower surface of the first contact plug 170A may be disposed on a lower level than a lower surface of the second contact plug 170B relative to the substrate 101. In an example, a cross-sectional area of the first contact plug 170A in contact with the first source/drain region 150A may be greater than a cross-sectional area of the second contact plug 170B in contact with the auxiliary epitaxial pattern 155.

The first and second insulating liners 130A and 130B may be disposed between the gate structure 160 and the first and second contact plugs 170A and 170B. In an example, the first insulating liner 130A may be disposed between the gate structure 160 and the first contact plug 170A. The second insulating liner 130B may be disposed between the gate structure 160 and the second contact plug 170B. The first insulating liner 130A may be in contact with side surfaces of the gate spacer layers 164 of the gate structure 160 and a side surface of the first conductive liner 174A. The second insulating liner 130B may be in contact with side surfaces of the gate spacer layers 164 of the gate structure 160 and a side surface of the second conductive liner 174B. In an example, lower surfaces of the first and second insulating liners 130A and 130B may be in contact with a portion of upper surfaces of the first and second source/drain regions 150A and 150B. The lower surface of the first insulating liner 130A may be in contact with the first portion of the second epitaxial layer 154A of the first source/drain region 150A. The lower surface of the second insulating liner 130B may be in contact with the first portion of the second epitaxial layer 154B of the second source/drain region 150B and the convex curved surface of the auxiliary epitaxial pattern 155.

A semiconductor device according to embodiments of the present inventive concept may include the first region R1 which is an nFET region and the second region R2 which is a pFET region, and may include the first contact plug 170A in contact with the first source/drain region 150A disposed in the first region R1 and the second contact plug 170B connected to the second source/drain region 150B through the auxiliary epitaxial pattern 155 disposed in the second region R2. In addition, in order to prevent a compressive stress applied to the channel structure 140 of the second region R2 from being reduced, a depth of the auxiliary epitaxial pattern 155 recessed by or extending into the second contact plug 170B may be formed to be less than a depth of the first source/drain region 150A recessed by or extending into the first contact plug 170A, so that the lower surface of the second contact plug 170B may be disposed on a level higher than a lower surface of the first contact plug 170A. Accordingly, a semiconductor device in which the contact resistance between the second contact plug 170B and the second source/drain region 150B is reduced, minimized or otherwise improved may be provided.

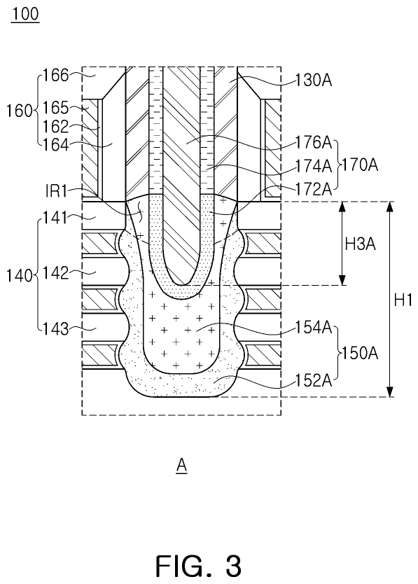

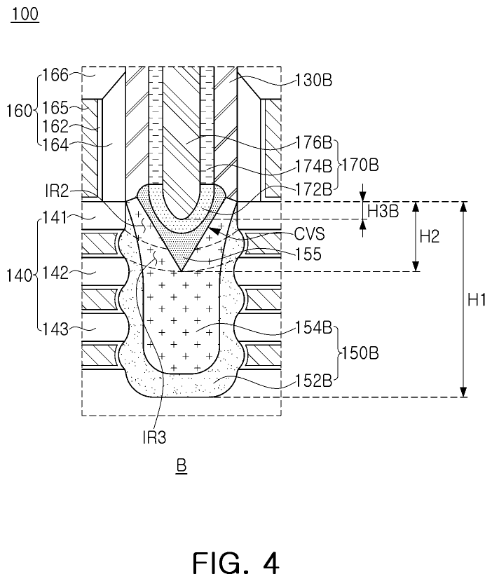

FIG. 3 is an enlarged view illustrating an embodiment of region A of the semiconductor device illustrated in FIG. 2A. FIG. 4 is an enlarged view showing an embodiment of region B of the semiconductor device illustrated in FIG. 2A.

Referring to FIGS. 3 and 4 along with FIG. 2A, the first source/drain region 150A disposed in the first region R1 of the semiconductor device 100 and the second source/drain region 150B disposed in the second region R2 may have a first height H1. The first height H1 may be a vertical length or distance (e.g., in the Z-direction) from upper surfaces to lower surfaces of the first and second source/drain regions 150A and 150B. For example, the first height H1 may be about 70 nm. In an embodiment, the cavity CVS of the second epitaxial layer 154B of the second source/drain region 150B may have a second height H2. The second height H2 of the cavity CVS may be a vertical length or distance (e.g., in the Z-direction) from an upper surface of the channel structure 140 to a lowermost bottom of the cavity CVS. The second height H2 may be between about 20 nm and about 25 nm. The first conductive layer 176A of the first contact plug 170A embedded in the first source/drain region 150A may have a third depth H3A, and the second conductive layer 176B of the second contact plug 170B embedded in the second source/drain region 150B may have a fourth depth H3B less than the third depth H3A. For example, the third depth H3A may be about 20 nm or more, and the fourth depth H3B may be between about 10 nm and about 15 nm.

The semiconductor device 100 may include a first impurity region IR1 positioned in the first source/drain region 150A and second impurity regions IR2 and IR3 positioned in the second source/drain region 150B. In an embodiment, an area (e.g., a collective cross-sectional area) of the second impurity regions IR2 and IR3 may be greater than an area of the first impurity region IR1.

The first impurity region IR1 may have a first depth from the upper surface of the first source/drain region 150A, and may include impurities of a first conductivity type (e.g., n-type), also referred to herein as first impurities. The first impurity region IR1 may be formed adjacent to an upper portion of the first source/drain region 150A across the first epitaxial layer 152A and the second epitaxial layer 154A in the first direction (X-direction). A lower surface (or lower boundary) of the first impurity region IR1 may be disposed on a level higher than the lower surface of the first contact plug 170A. The first impurity region IR1 may be in contact with channel structures 140 disposed on both (e.g., opposing) sides of the first source/drain region 150A. However, the present inventive concept is not limited thereto, and the range and thickness of the first impurity region IR1 may be variously changed. The first impurity region IR1 may be a region having the highest impurity concentration in the first source/drain region 150A.

The second impurity regions IR2 and IR3 may have a second depth, greater than the first depth of the first impurity region IR1, from an upper surface of the second source/drain region 150B, and may include impurities of a second conductivity type (e.g., p-type; also referred to herein as second impurities) different from the first impurities of the first impurity region IR1. The second impurity regions IR2 and IR3 may be formed adjacent to an upper portion of the second source/drain region 150B across the first epitaxial layer 152B and the second epitaxial layer 154B in the first direction (X-direction). The second impurity regions IR2 and IR3 may be in contact with one or more of the channel structures 140 disposed on both (e.g., opposing) sides of the second source/drain region 150B.

The second impurity regions IR2 and IR3 may include a (2-1)-th impurity region IR2 and a (2-2)-th impurity region IR3 having a lower surface (or lower boundary) on a level lower than a lower surface of the (2-1)-th impurity region IR2. The lower surface (or lower boundary) of the (2-2)-th impurity region IR3 may be disposed on the same level as or a level lower than a lower portion of the cavity CVS of the second source/drain region 150B. The lower surface (or lower boundary) of the (2-1)-th impurity region IR2 may be disposed on the same level as a lower surface (or lower boundary) of the first impurity region IR1, but the present inventive concept is not limited thereto. In an example, the lower surface of the (2-1)-th impurity region IR2 may be disposed on a level different from the lower surface (or lower boundary) of the first impurity region IR1. The lower surface of the (2-2)-th impurity region IR3 may be disposed on a level lower than the lower surface (or lower boundary) of the first impurity region IR1.

The second impurity regions IR2 and IR3 may be regions with a comparatively higher impurity concentration in the second source/drain region 150B. The second impurity regions IR2 and IR3 may have impurity concentrations higher than those of the remaining regions of the second source/drain region 150B excluding regions where the second impurity regions IR2 and IR3 are disposed. The impurity concentration of the (2-1)-th impurity region IR2 may be greater than the impurity concentration of the (2-2)-th impurity region IR3. However, the present inventive concept is not limited thereto, and the impurity concentration of the (2-1)-th impurity region IR2 may be the same as the impurity concentration of the (2-2)-th impurity region IR3 in some embodiments.

The first impurity region IR1 and the second impurity regions IR2 and IR3 may include different impurities from each other. The first impurity region IR1 may include N-type impurities, such as at least one of phosphorus (P), arsenic (As) or antimony (Sb), or at least one of carbon (C) or argon (Ar). The second impurity regions IR2 and IR3 may include P-type impurities, such as at least one of boron (B), gallium (Ga) or indium (In).

The semiconductor device according to embodiments of the present inventive concept may include the first region R1 which is an nFET region and the second region R2 which is a pFET region, and may include the first contact plug 170A in contact with the first source/drain region 150A disposed in the first region R1 and the second contact plug 170B connected to the second source/drain region 150B through the auxiliary epitaxial pattern 155 disposed in the second region R2, which may reduce contact resistance therebetween. In addition, the semiconductor device may comprise the first impurity region IR1 positioned in the first source/drain region 150A of the first region R1, and the second impurity regions IR2 and IR3 positioned in the second source/drain region 150B of the second region R2 and having an area greater than that of the first impurity region IR1. Accordingly, the impurities of the second impurity regions IR2 and IR3 may diffuse into the channel structures 140 to improve (e.g., reduce) channel resistance in the pFET region, thereby providing the semiconductor device with improved electrical characteristics.

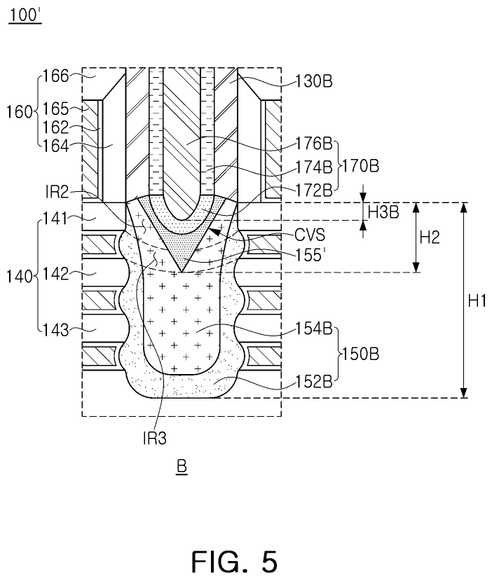

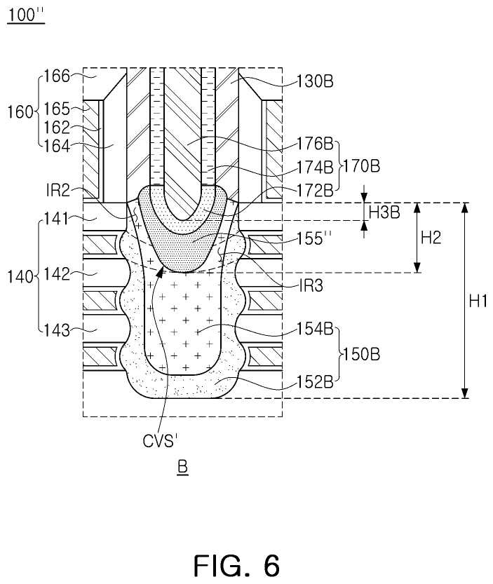

FIGS. 5 and 6 are enlarged views illustrating other embodiments of region B of the semiconductor device illustrated in FIG. 2A.

Referring to FIG. 5, the remaining configurations except for an auxiliary epitaxial pattern 155′ accommodated in the cavity CVS of a semiconductor device 100′ may be the same as or corresponding to the configurations illustrated in FIG. 4. Among the configurations except for the auxiliary epitaxial pattern 155′, the description of the components identical or corresponding to the configurations illustrated in FIG. 4 will be omitted.

An upper surface of the auxiliary epitaxial pattern 155′ may be disposed on the same level as or may define a continuous surface with an upper surface of the second epitaxial layer 154B of the second source/drain region 150B. However, the present inventive concept is not limited thereto, and the upper surface of the auxiliary epitaxial pattern 155′ may be disposed on a level lower than the upper surface of the second epitaxial layer 154B in some embodiments.

Referring to FIG. 6, the remaining configurations except for an auxiliary epitaxial pattern 155″ accommodated in a cavity CVS′ of a semiconductor element 100″ may be identical or corresponding to the configurations illustrated in FIG. 4. The description of the components identical or corresponding to the configurations illustrated in FIG. 4 except for the auxiliary epitaxial pattern 155″ will be omitted.

An upper surface of the second source/drain region 150B may include a cavity CVS′ having an inner curved surface recessed toward a substrate (e.g., the substrate 101 of FIG. 2A). That is, an outer surface of the second epitaxial layer 154B may include a first portion and a second portion extending from the first portion, in which the cavity CVS′ is arranged. A lower surface (or inner surface) of the auxiliary epitaxial pattern 155″ may have a convex curved surface protruding toward the device isolation layer 110 in correspondence to the shape of the cavity CVS′ of the second epitaxial layer 154B. An upper surface of the auxiliary epitaxial pattern 155″ may be disposed on a higher level than the upper surface of the second epitaxial layer 154B. That is, the upper surface of the auxiliary epitaxial pattern 155″ may have a convex surface protruding in the vertical third direction (Z-direction).

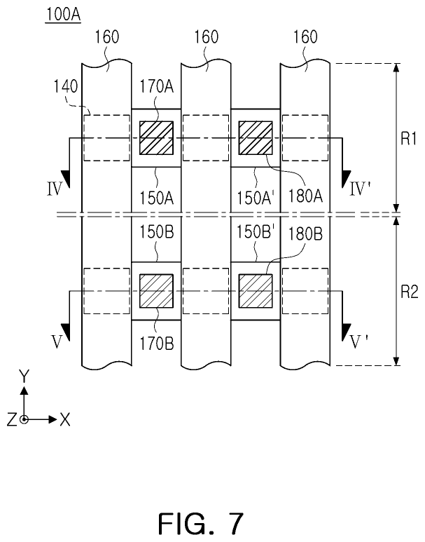

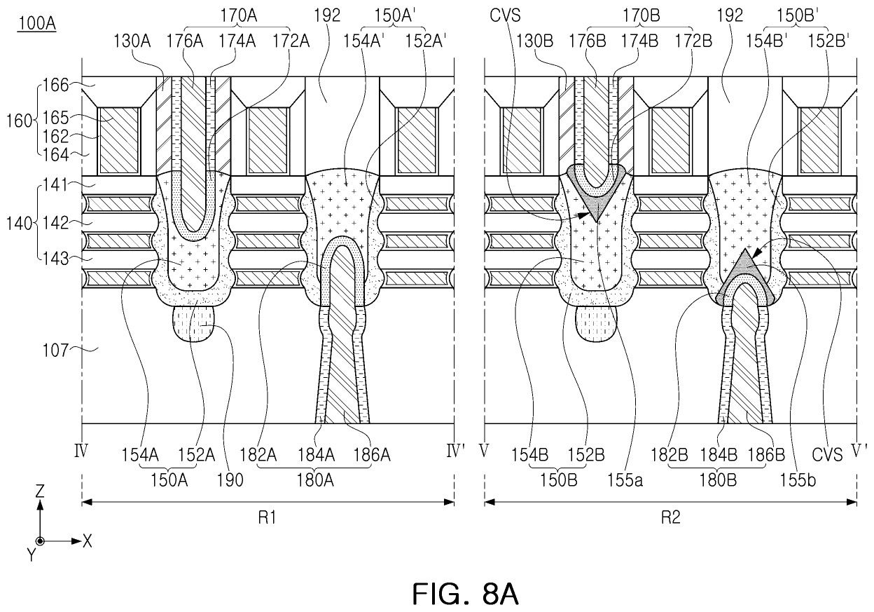

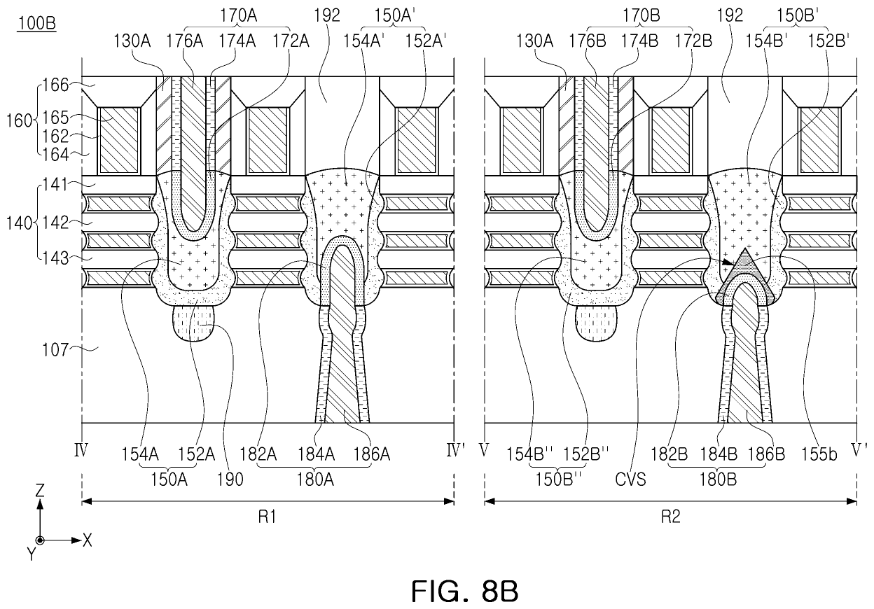

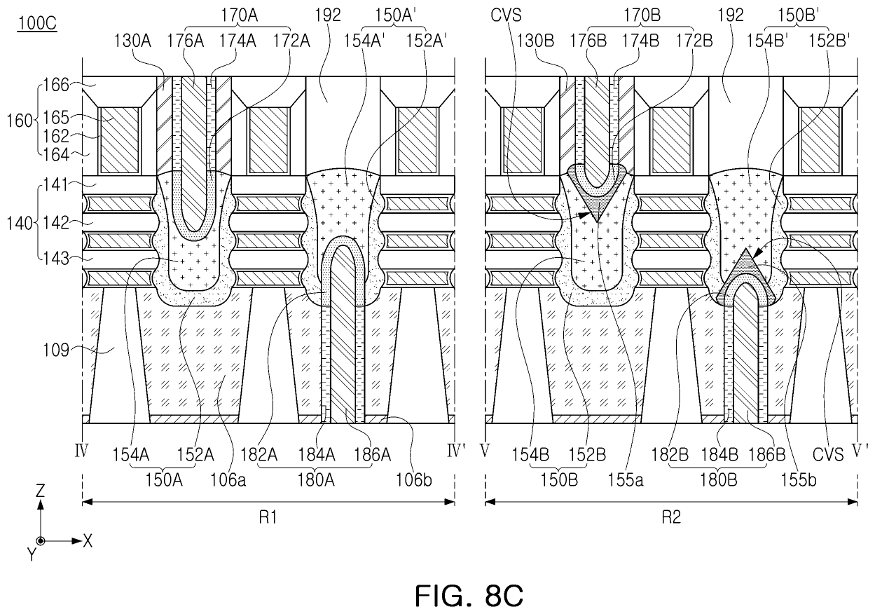

FIG. 7 is a plan view illustrating a semiconductor device 100A according to another embodiment of the present inventive concept. FIGS. 8A to 8C are cross-sectional views illustrating embodiments of the semiconductor device illustrated in FIG. 7 along lines IV-IV′ and V-V′.

Referring to FIGS. 7 and 8A, the semiconductor device 100A may include a substrate insulating layer 107 having first and second regions R1 and R2, gate structures 160 extending on the substrate insulating layer 107 and each including a gate electrode 165, channel structures 140 including first to third channel layers 141, 142 and 143 vertically spaced apart from each other on the substrate insulating layer 107, first to fourth source/drain regions 150A, 150B, 150A′ and 150B′ in contact with the channel structures 140, a first front contact plug 170A penetrating an interlayer insulating layer 192 and connected to the first source/drain region 150A, a second front contact plug 170B penetrating the interlayer insulating layer 192 and connected to the second source/drain region 150B, a first backside contact plug 180A penetrating the substrate insulating layer 107 and connected to third source/drain regions 150A′, a second backside contact plug 180B penetrating the substrate insulating layer 107 and connected to the fourth source/drain regions 150B′, a first auxiliary epitaxial pattern 155a disposed between the second source/drain region 150B and the second front contact plug 170B, and a second auxiliary epitaxial pattern 155b disposed between the fourth source/drain region 150B′ and the second backside contact plug 180B. The semiconductor device 100A may further include placeholder layers 190 and the interlayer insulating layer 192 below the first and second source/drain regions 150A and 150B.

The substrate insulating layer 107 may have an upper surface extending in a first direction (X-direction) and a second direction (Y-direction). The substrate insulating layer 107 may be a layer formed by removing and/or oxidizing a substrate made of a semiconductor material during a manufacturing process. The substrate insulating layer 107 may be made of an insulating material, and may include, for example, an oxide, a nitride or a combination thereof. Depending on embodiments, the substrate insulating layer 107 may include a plurality of insulating layers.

The substrate insulating layer 107 may include first and second regions R1 and R2, and the first and second regions R1 and R2 may be adjacent to or spaced apart from each other. In the first region R1, the first and third source/drain regions 150A and 150A′, the first front contact plug 170A and the first backside contact plug 180A may be disposed, and in the second region R2, the second and fourth source/drain regions 150B and 150B′, the second front contact plug 170B and the second backside contact plug 180B may be disposed. For example, the first region R1 may be an nFET region, and the second region R2 may be a pFET region.

The gate structures 160 may extend in one direction, for example, in the second direction (Y-direction), on the substrate insulating layer 107. Channel regions of transistors may be formed in the channel structures 140 intersecting the gate electrodes 165 of the gate structures 160. The gate structures 160 may be spaced apart from each other in the first direction (X-direction). Each of the gate structures 160 may include gate dielectric layers 162, gate spacer layers 164, a gate electrode 165 and a gate capping layer 166.

The channel structures 140 may be disposed on the substrate insulating layer 107 so as to intersect the gate structures 160. Each of the channel structures 140 may include two or more plurality of channel layers, for example, the first to third channel layers 141, 142 and 143, which are spaced apart from each other in the third direction (Z-direction). The channel structure 140 may be connected to the first to fourth source/drain regions 150A, 150B, 150A′ and 150B′.

The first to fourth source/drain regions 150A, 150B, 150A′ and 150B′ may be disposed so as to be in contact with the channel structures 140 on both (e.g., opposing) sides of the gate structure 160. The first to fourth source/drain regions 150A, 150B, 150A′ and 150B′ may be disposed to cover side surfaces of each of the first to third channel layers 141, 142 and 143 of the channel structure 140 in the first direction (X-direction). The first source/drain region 150A may be connected to the first front contact plug 170A through an upper surface or top thereof, and the third source/drain regions 150A′ may be connected to the first backside contact plugs 180A through a lower surface or bottom thereof, respectively. The first source/drain region 150A may have a shape recessed by the first front contact plug 170A. The second source/drain region 150B may be connected to the first auxiliary epitaxial pattern 155a through an upper surface or top thereof, and the fourth source/drain region 150B′ may be connected to the second auxiliary epitaxial pattern 155b through a lower surface or bottom thereof. The second source/drain region 150B may have a recessed shape that is penetrated by the first auxiliary epitaxial pattern 155a. The recessed shape formed in the second source/drain region 150B may be a shape protruding toward the substrate insulating layer 107. The fourth source/drain region 150B′ may have a recessed shape that is penetrated by the second auxiliary epitaxial pattern 155b. The recessed shape formed in the fourth source/drain region 150B′ may be a shape protruding toward the interlayer insulating layer 192.

The first to fourth source/drain regions 150A, 150B, 150A′ and 150B′ may include first epitaxial layers 152A, 152B, 152A′ and 152B′ and a second epitaxial layer 154A, 154B, 154A′ and 154B′, respectively. The first epitaxial layer 152A, 152B, 152A′ and 152B′ may cover side surfaces of each of the first to third channel layers 141, 142 and 143 along the first direction (X-direction), and may cover side surfaces of a gate structure 160 below the channel structure 140 along the first direction (X-direction). The first epitaxial layer 152A, 152B, 152A′ and 152B′ may extend to cover an inner wall and a bottom surface of a recessed region in which the first to fourth source/drain regions 150A, 150B, 150A′ and 150B′ are arranged, respectively. The first epitaxial layer 152A, 152B, 152A′ and 152B′ may have outer surfaces convexly protruding toward the substrate insulating layer 107 from below the first to third channel layers 141, 142 and 143, and thus may have curves in the outer surfaces. However, the outer surfaces of the first epitaxial layer 152A, 152B, 152A′ and 152B′ are not limited to the shapes illustrated in FIG. 8A. In the third source/drain region 150A′, the first epitaxial layer 152A′ may be penetrated by the first backside contact plug 180A, and may be in contact with the first backside contact plug 180A. In the fourth source/drain region 150B′, the first epitaxial layer 152B′ may be penetrated by the second auxiliary epitaxial pattern 155b and the second backside contact plug 180B, and may be in contact with the second backside contact plug 180B.

The second epitaxial layers 154A, 154B, 154A′ and 154B′ may cover the first epitaxial layers 152A, 152B, 152A′ and 152B′, and fill the recessed region. In the third source/drain region 150A′, the second epitaxial layer 154A′ may be in contact with at least one region of a top of the first backside contact plug 180A. In the fourth source/drain region 150B′, the second epitaxial layer 154B′ may be in contact with a portion of a top of the second auxiliary epitaxial pattern 155b.

The first to fourth source/drain regions 150A, 150B, 150A′ and 150B′ may include a semiconductor material such as at least one of silicon (Si) or germanium (Ge), and may further include impurities. A concentration of a non-silicon element of the second epitaxial layer 154A, 154B, 154A′ and 154B′ may be greater than a concentration of a non-silicon element of the first epitaxial layer 152A, 152B, 152A′ and 152B′. The non-silicon element may be, for example, germanium (Ge) and/or a doping element. For example, when the first region R1 is an nFET region and the second region R2 is a pFET region, the first and third source/drain regions 150A and 150A′ may not include germanium (Ge) or may include germanium (Ge) at a lower concentration the than those of the second and fourth source/drain regions 150B and 150B′. For example, the first and third source/drain regions 150A and 150A′ may include silicon (Si), and the second and fourth source/drain regions 150B and 150B′ may include silicon germanium (SiGe).

The second epitaxial layer 154A of the first source/drain region 150A may include an inner surface in contact with the first epitaxial layer 152A and an outer surface concavely formed toward the substrate insulating layer 107 and having a recessed surface in contact with the first front contact plug 170A.

The second epitaxial layer 154A′ of the third source/drain region 150A′ may have an inner surface in contact with the first epitaxial layer 152A′ and the first backside contact plug 180A, and an outer surface in contact with the interlayer insulating layer 192.

The first backside contact plug 180A may include a first conductive layer 186A, a first metal-semiconductor compound layer 182A disposed between the first conductive layer 186A and the third source/drain region 150A′, and a first conductive liner 184A extending from the first metal-semiconductor compound layer 182A and surrounding a side surface of the first conductive layer 186A. The side surface of the first conductive liner 184A may be in contact with the substrate insulating layer 107. The first metal-semiconductor compound layer 182A may be disposed on a recessed region of the lower surface of the third source/drain region 150A′, and may be in contact with the first and second epitaxial layers 152A′ and 154A′.

The second epitaxial layer 154B of the second source/drain region 150B may include an inner surface in contact with the first epitaxial layer 152B and an outer surface including a cavity CVS having an inclined surface toward the substrate insulating layer 107. The cavity CVS formed on the outer surface of the second epitaxial layer 154B may be a growth surface of the first auxiliary epitaxial pattern 155a. For example, the cavity CVS of the second epitaxial layer 154B may have an inclined surface having a (1 1 1) crystal plane. The cavity CVS of the second source/drain region 150B may have a shape whose width increases as it goes upward, i.e., with distance from the substrate insulating layer 107. The first auxiliary epitaxial pattern 155a may be disposed in the cavity CVS of the second source/drain region 150B. The first auxiliary epitaxial pattern 155a may correspond to the auxiliary epitaxial pattern 155 of FIG. 2A.

The fourth source/drain region 150B′ may include a cavity CVS having an inclined surface from the outer surface of the first epitaxial layer 152B′ toward the inner surface of the second epitaxial layer 154B′. The cavity CVS of the fourth source/drain region 150B′ may have a shape whose width becomes narrower as it goes upward, i.e., with distance from the substrate insulating layer 107. The second auxiliary epitaxial pattern 155b may be formed in the cavity CVS of the fourth source/drain region 150B′. The second auxiliary epitaxial pattern 155b may be an epitaxial pattern grown along the cavity CVS of the fourth source/drain region 150B′. An upper surface (or inner surface) of the second auxiliary epitaxial pattern 155b may be in contact with the first epitaxial layer 152B′ and the second epitaxial layer 154B′ along the inclined surface. The lower surface (or outer surface) of the second auxiliary epitaxial pattern 155b may have a recessed shape by the second backside contact plug 180B. The recessed shape of the second auxiliary epitaxial pattern 155b may be a shape protruding toward the second epitaxial layer 154B′.

The second backside contact plug 180B may include a second conductive layer 186B, a second metal-semiconductor compound layer 182B disposed between the second conductive layer 186B and the second auxiliary epitaxial pattern 155b, and a second conductive liner 184B extending from the second metal-semiconductor compound layer 182B and surrounding a side surface of the second conductive layer 186B. The side surface of the second conductive liner 184B may be in contact with the substrate insulating layer 107. The second metal-semiconductor compound layer 182B may be disposed on the recessed the lower surface of the second auxiliary epitaxial pattern 155b, and may be in contact with the second auxiliary epitaxial pattern 155b.

A height or length of the second backside contact plug 180B embedded in the second auxiliary epitaxial pattern 155b may be less than a height or length of the first backside contact plug 180A embedded in the lower surface of the third source/drain region 150A′, e.g., in the vertical (or Z−) direction.

A height or length of the second front contact plug 170B embedded in the first auxiliary epitaxial pattern 155a may be substantially the same as a height or length of the second backside contact plug 180B embedded in the second auxiliary epitaxial pattern 155b. A height or length of the first backside contact plug 180A embedded in a lower surface of the third source/drain region 150A′ may be substantially the same as a height or length of the first front contact plug 170A embedded in an upper surface of the first source/drain region 150A, e.g., in the vertical (or Z−) direction.

Although not shown, the semiconductor device 100A may further include a first impurity region (e.g., the first impurity region IR1 in FIG. 3) positioned in the first and third source/drain regions 150A and 150A′, and may further include second impurity regions (e.g., the second impurity regions IR2 and IR3 in FIG. 4) positioned in the second and fourth source/drain regions 150B and 150B′. The first impurity region positioned in the third source/drain region 150A′ may be formed adjacent to a bottom portion of the third source/drain region 150A′ across the first and second epitaxial layers 152A′ and 154A′ in the first direction (X-direction). The second impurity regions positioned in the fourth source/drain region 150B′ may be formed adjacent to a bottom portion of the fourth source/drain region 150B′ across the first and second epitaxial layers 152B′ and 154B′ in the first direction (X-direction). A top portion of the second impurity regions positioned in the fourth source/drain region 150B′ may be disposed on a level higher than a top portion of the first impurity region positioned in the third source/drain region 150A′. In an example, an area (e.g., in cross-section) of the second impurity regions positioned in the second and fourth source/drain regions 150B and 150B′ may be greater than an area of the first impurity region positioned in the first and third source/drain regions 150A and 150A′.

Referring to FIG. 8B, the remaining configurations except for a second source/drain region 150″ in a semiconductor device 100B may correspond to the configurations illustrated in FIG. 8A.

The semiconductor device 100B may have the second auxiliary epitaxial pattern 155b positioned only between the fourth source/drain region 150B′ and the second backside contact plug 180B.

The second source/drain region 150B″ may include a first epitaxial layer 152B″ and a second epitaxial layer 154B″ on the first epitaxial layer 152B″. The first epitaxial layer 152B″ of the second source/drain region 150B″ may correspond to the first epitaxial layer 152B of FIG. 2A. The second epitaxial layer 154B″ may include an inner surface in contact with the first epitaxial layer 152B″ and an outer surface concavely formed toward the substrate insulating layer 107 and having a recessed surface in contact with the second front contact plug 170B. A depth of the second front contact plug 170B embedded in the second epitaxial layer 154B″ of the second source/drain region 150B″ may be greater than a depth of the second backside contact plug 180B embedded in the second auxiliary epitaxial pattern 155b.

Referring to FIG. 8C, a semiconductor device 100C may further include active regions 106a, liner layers 106b and isolation structures 109, and may not include the substrate insulating layer 107 and the placeholder layers 190 in FIG. 8A.

The liner layers 106b may extend horizontally along lower surfaces of the active regions 106a. The liner layers 106b may function as etch-stop layers during a manufacturing process of the semiconductor device 100C, and may include, for example, SiGe. The liner layers 106b may include an insulating material. For example, the liner layers 106b may include an oxide and/or a nitride. The description of the active regions 106a may be similar or identical to the description of the active regions 105 described above with reference to FIGS. 2A and 2B.

The isolation structures 109 may be disposed on lowermost surfaces of the gate structures 160. The isolation structures 109 may penetrate the liner layers 106b and the active regions 106a, and may be connected to the gate structures 160.

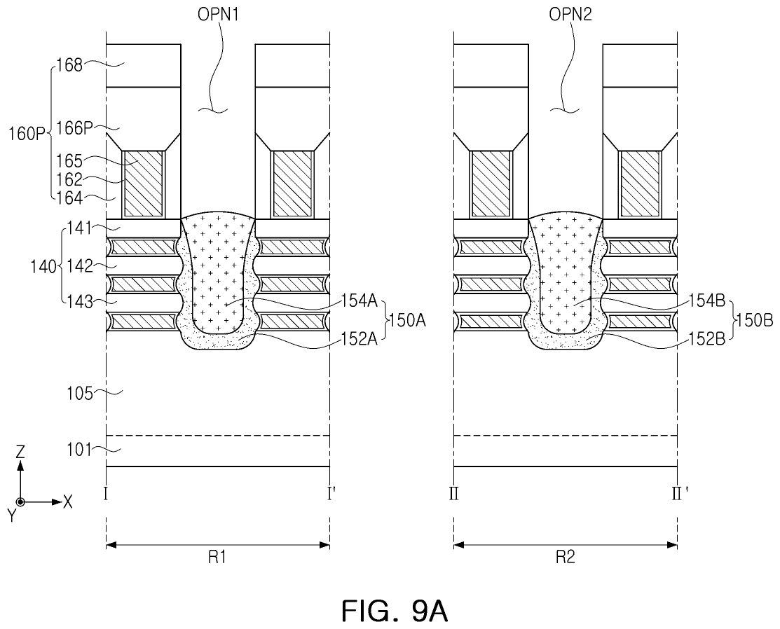

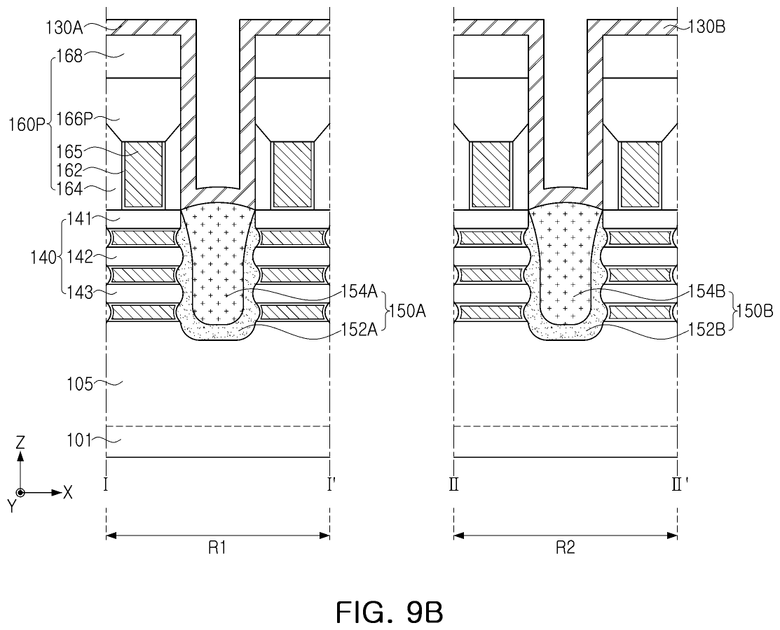

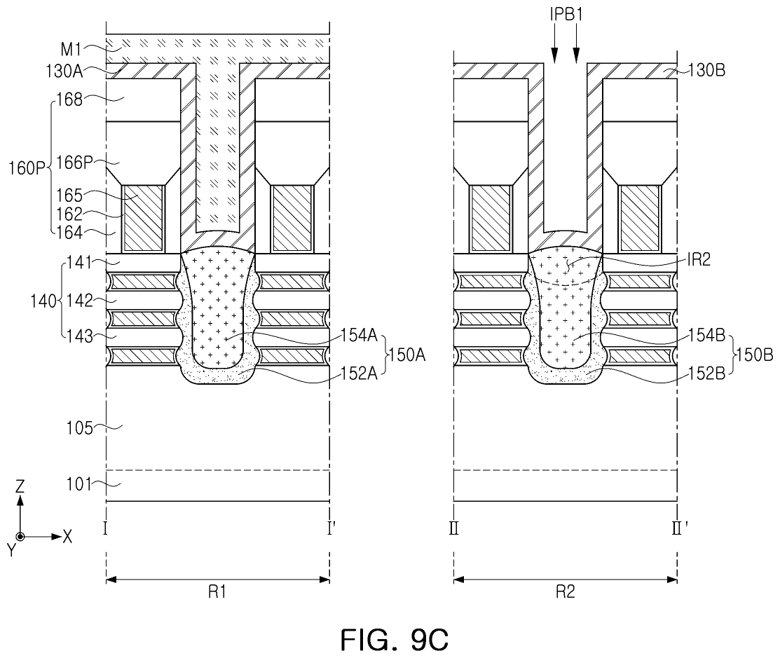

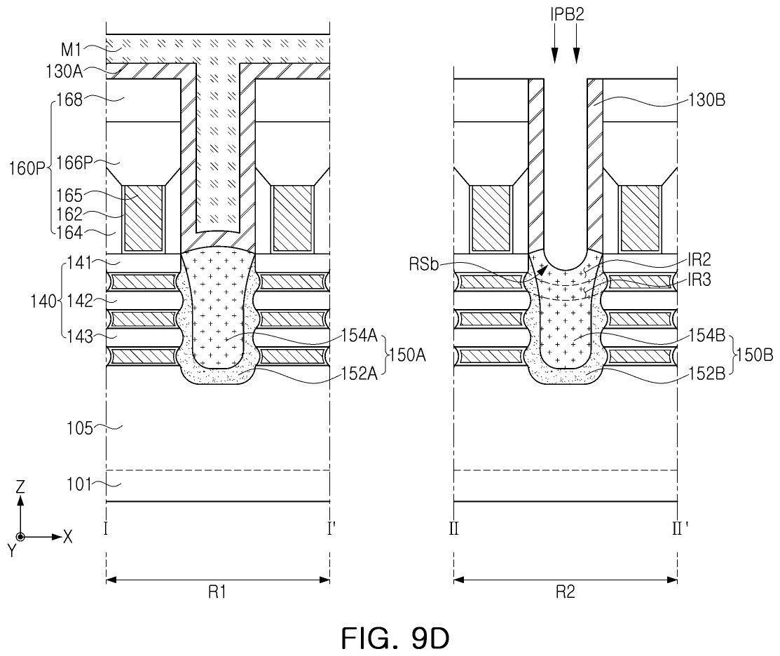

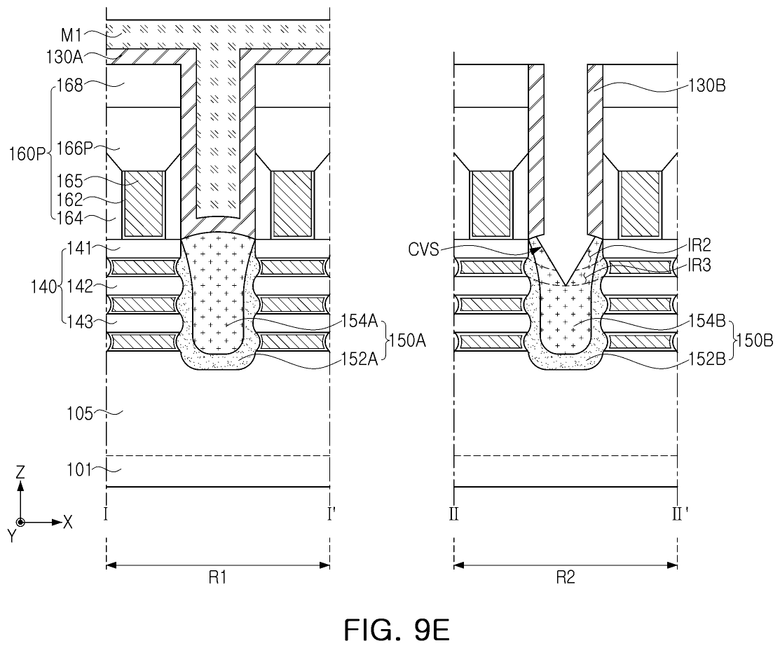

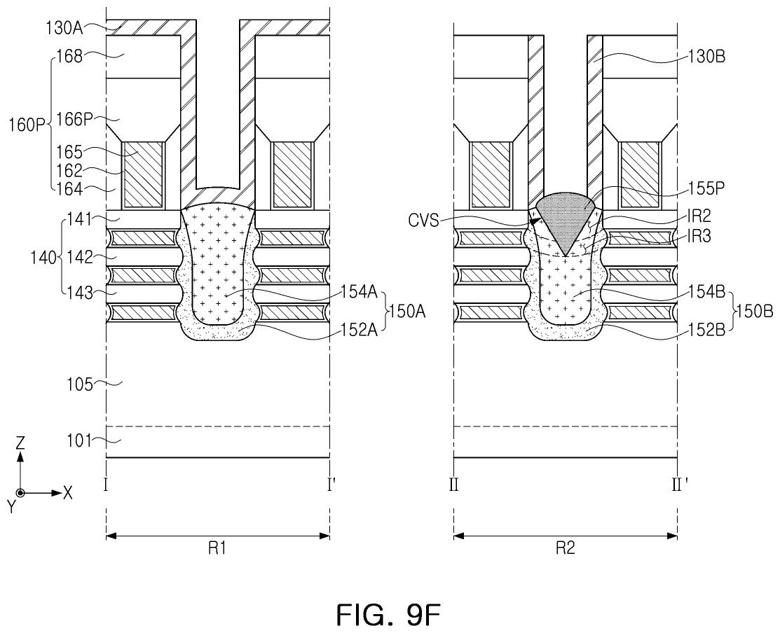

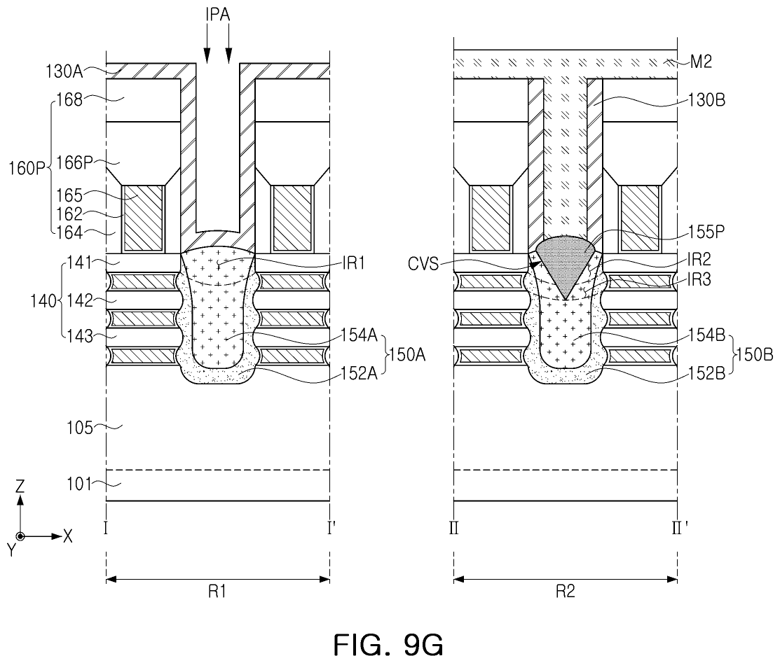

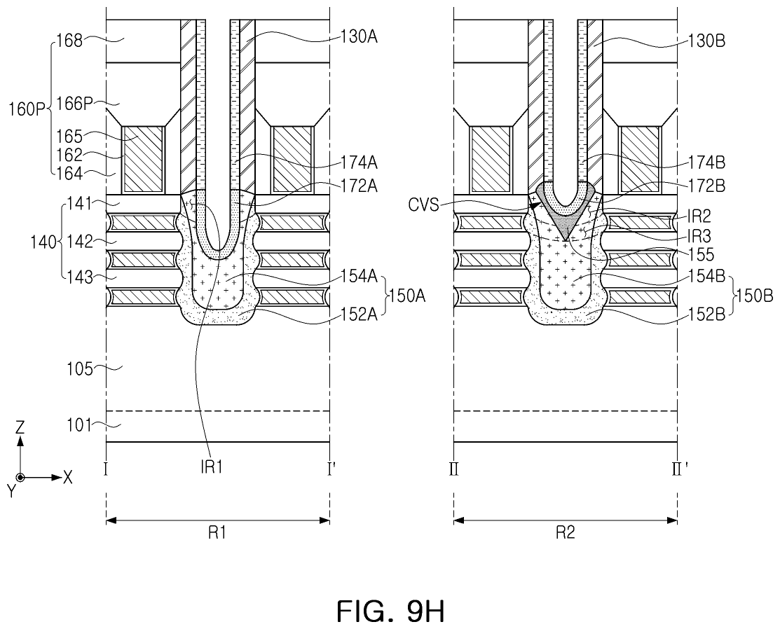

FIGS. 9A to 9H are cross-sectional views illustrating an embodiment of a method for manufacturing the semiconductor device in FIG. 2A. FIGS. 9A to 9H each illustrate cross-sections taken along the cutting lines I-I′ and II-II′ of FIG. 1.

Referring to FIG. 9A, the method may include an operation of forming the channel structure 140 by stacking the first to third channel layers 141, 142 and 143 on the substrate 101, an operation of forming the first and second source/drain regions 150A and 150B, and an operation of forming a preliminary gate structure 160P.

The substrate 101 may include silicon (Si), germanium (Ge) or silicon germanium (SiGe). The substrate 101 may include a bulk wafer, an epitaxial layer, a Silicon On Insulator (SOI) layer or a Semiconductor On Insulator (SeOI) layer.

The first to third channel layers 141, 142 and 143 may be formed by performing an epitaxial growth process from the substrate 101. The number of layers of the channel layers 141, 142 and 143 may vary in embodiments.

The first to third channel layers 141, 142 and 143 and a portion of the substrate 101 may be removed to form active structures, and the active structures may further include the active regions 105 formed by removing the portion of the substrate 101 to protrude from the substrate 101. The active regions 105 may include different impurities (e.g., impurities of opposite conductivity types) in the first and second regions R1 and R2. However, in some embodiments, the active regions 105 may not include impurities (e.g., may not include implanted impurities; also referred to herein as undoped). A device isolation layer may be formed between adjacent active regions 105.

The first and second source/drain regions 150A and 150B may be formed by selective epitaxial growth from side surfaces of the channel structures 140 and the active regions 105. The first source/drain region 150A and the second source/drain region 150B may be formed by different processes, and may have different compositions. The first and second source/drain regions 150A and 150B may include impurities by in-situ doping. The first and second source/drain regions 150A and 150B may include the first epitaxial layers 152A and 152B and the second epitaxial layers 154A and 154B on the first epitaxial layers 152A and 152B, respectively.

The operation of forming the preliminary gate structure 160P may include an operation of sequentially forming the gate spacer layers 164, the gate dielectric layers 162, the gate electrodes 165, a first gate capping layer 166P, and a second gate capping layer 168. The first gate capping layer 166P and the second gate capping layer 168 may be an insulating material, such as an oxide, a nitride or a combination thereof. In an example, the first gate capping layer 166P may include a first insulating material, and the second gate capping layer 168 may include a second insulating material different from the first insulating material. For example, the first gate capping layer 166P may include silicon nitride, and the second gate capping layer 168 may include oxide.

A first opening OPN1 exposing the first source/drain region 150A and a second opening OPN2 exposing the second source/drain region 150B may be formed between the gate structures 160. The term “exposed” may be used to describe relationships between elements and/or certain intermediate processes in fabricating a completed semiconductor device, but may not necessarily require exposure of the particular region, layer, structure or other element in the context of the completed device.

Referring to FIG. 9B, the first and second insulating liners 130A and 130B may be formed to cover the upper surface of the first source/drain region 150A exposed through the first opening OPN1, the upper surface of the second source/drain region 150B exposed through the second opening OPN2, and the upper surfaces and the side surfaces of the gate structures 160. The first and second insulating liners 130A and 130B may include silicon nitride.

Referring to FIG. 9C, a first mask pattern M1 covering the first region R1 of the semiconductor device 100 may be formed, and a (1-1)-th ion implantation process IPB1 may be performed on the second source/drain region 150B of the second region R2 to form the (2-1)-th impurity region IR2.

The first mask pattern M1 may be a photoresist pattern. In another example, the first mask pattern M1 may have at least one single-layer or multi-layer structure selected from Spin on Hardmask (SOH) and Amorphous carbon layer (ACL).

P-type impurities, such as at least one of boron (B), gallium (Ga) or indium (In), may be implanted into the second source/drain region 150B covered by the second insulating liner 130B. The (1-1)-th ion implantation process IPB1 may be an ion implantation process. The (2-1)-th impurity region IR2 formed by the (1-1)-th ion implantation process IPB1 may have a first depth from the upper surface of the second source/drain region 150B.

Referring to FIG. 9D, the second insulating liner 130B overlapping the second source/drain region 150B may be removed, and a (1-2)-th ion implantation process IPB2 may be performed to form the (2-2)-th impurity region IR3. Components or layers described with reference to “overlap” in a particular direction may be at least partially obstructed by one another when viewed along a line extending in the particular direction or in a plane perpendicular to the particular direction.

In a state where the first mask pattern M1 covers the first region R1, the second insulating liner 130B overlapping the second source/drain region 150B and the second gate capping layer 168 may be removed through a residue process for the second source/drain region 150B of the second region R2. The residue process may be an anisotropic etching process and may use an etching gas. The etching gas may include Cl₂, CHF₃, CF₄ or a combination thereof, and Ar or O₂ gas. The residue process for the second source/drain region 150B may be performed to remove the second insulating liner 130B and a portion of the second source/drain region 150B. By performing the residue process, silicon germanium (SiGe) of the second source/drain region 150B may be removed, thereby forming an inner surface convexly formed toward the substrate 101. Through the residue process, a vertical height of the second epitaxial layer 154B of the second source/drain region 150B may be reduced, for example, by about 7 to 8 nm.

After performing the residue process on the second source/drain region 150B, the (1-2)-th ion implantation process IPB2 may be performed on the second epitaxial layer 154B of the second source/drain region 150B exposed between the gate structures 160.

P-type impurities, such as at least one of boron (B), gallium (Ga) or indium (In), may be implanted into the second source/drain region 150B exposed between the gate structures 160. The (1-2)-th ion implantation process IPB2 may be performed by an ion implant process.

The (2-2)-th impurity region IR3 formed by the (1-2)-th ion implantation process IPB2 may have a second depth greater than the first depth of the (2-1)-th impurity region IR2 from the upper surface of the second source/drain region 150B. A lower surface or boundary of the (2-2)-th impurity region IR3 may be disposed on a level lower than a lower surface or boundary of the (2-1)-th impurity region IR2, relative to the substrate 101.

Referring to FIG. 9E, the cavity CVS having an inclined surface or facet may be formed by partially removing the second epitaxial layer 154B exposed through a concave inner side frame of the second source/drain region 150B. The cavity CVS having an inclined surface may be formed through a dry or wet etching process on the outer surface (e.g., the surface exposed between the gate structures 160) of the second epitaxial layer 154B. For example, the etching process may be formed by controlling the etching to proceed at different etching rates for crystal planes. The inclined surface may be a {111} crystal plane for the second epitaxial layer 154B, for example, a (1 1 1) crystal plane.

Referring to FIG. 9F, an auxiliary epitaxial pattern 155P may be formed in the cavity CVS. The auxiliary epitaxial pattern 155P may be formed by being grown by a selective epitaxial process using the surface of the cavity CVS as a seed layer. The auxiliary epitaxial pattern 155P may be formed such that an upper surface of the auxiliary epitaxial pattern 155P is positioned at a level higher than the upper surface of the second source/drain region 150B, relative to the substrate 101. The auxiliary epitaxial pattern 155P may have a higher concentration than a concentration of a non-silicon element of the first epitaxial layer 152B and a concentration of a non-silicon element of the second epitaxial layer 154B.

The first mask pattern M1 covering the first region R1 may be removed before or after the process of forming the auxiliary epitaxial pattern 155P.

Referring to FIG. 9G, a second mask pattern M2 covering the second region R2 of the semiconductor device 100 may be formed, and a second ion implantation process IPA may be performed on the first source/drain region 150A of the first region R1 to form the first impurity region IR1.

The second mask pattern M2 may be a photoresist pattern. In another example, the second mask pattern M2 may have at least one single-layer or multi-layer structure selected from Spin on Hardmask (SOH) and Amorphous carbon layer (ACL).

In a state covered by the first insulating liner 130A, N-type impurities, such as at least one of phosphorus (P), arsenic (As) or antimony (Sb), may be implanted into the first source/drain region 150A. The second ion implantation process IPA may be performed by an ion implant process.

A lower surface (or lower boundary) of the first impurity region IR1 may be disposed on a level than higher the lower surface (or lower boundary) of the (2-2)-th impurity region IR3, relative to the substrate 101.

Referring to FIG. 9H, a first metal-semiconductor compound layer 172A and a first conductive liner 174A extending into (also referred to herein as “recessing”) the upper surface of the first source/drain region 150A may be formed, and the second metal-semiconductor compound layer 172B and the second conductive liner 174B recessing the upper surface of the auxiliary epitaxial pattern 155P may be formed.

A first protective layer (not shown) recessing an upper surface of the first source/drain region 150A may be deposited, and a heat treatment process may be sequentially performed, so that a portion of the first protective layer in contact with the second epitaxial layer 154A may react with the second epitaxial layer 154A. Accordingly, the first metal-semiconductor compound layer 172A may be formed in the portion of the first protective layer in contact with the second epitaxial layer 154A, and the first conductive liner 174A may be formed in the remaining portion that is not in contact with the second epitaxial layer 154A. In a process of forming a second protective layer (not shown), a portion of an upper surface of the auxiliary epitaxial pattern 155P may be removed, so that an auxiliary epitaxial pattern 155 having a convex inner surface toward the substrate 101 may be formed. The second protective layer recessing an upper surface of the auxiliary epitaxial pattern 155P may be deposited, and a heat treatment process may be sequentially performed, so that a portion of the second protective layer in contact with the auxiliary epitaxial pattern 155 may react with the auxiliary epitaxial pattern 155. Accordingly, the second metal-semiconductor compound layer 172B may be formed in the portion of the second protective layer in contact with the auxiliary epitaxial pattern 155, and the second conductive liner 174B may be formed in the remaining portion that is not in contact with the auxiliary epitaxial pattern 155.

The second mask pattern M2 may be removed prior to the process of forming the second metal-semiconductor compound layer 172B and the second conductive liner 174B.

Next, referring to FIGS. 2A and 9H, the first conductive layer 176A may be formed on the first metal-semiconductor compound layer 172A and the first conductive liner 174A, and the second conductive layer 176B may be formed on the second metal-semiconductor compound layer 172B and the second conductive liner 174B. After forming the first conductive layer 176A and the second conductive layer 176B, a portion of the first gate capping layer 166P and the second gate capping layer 168 may be removed by a grinding and/or polishing process. As a result, the semiconductor device 100 of FIGS. 1 to 2B may be manufactured.

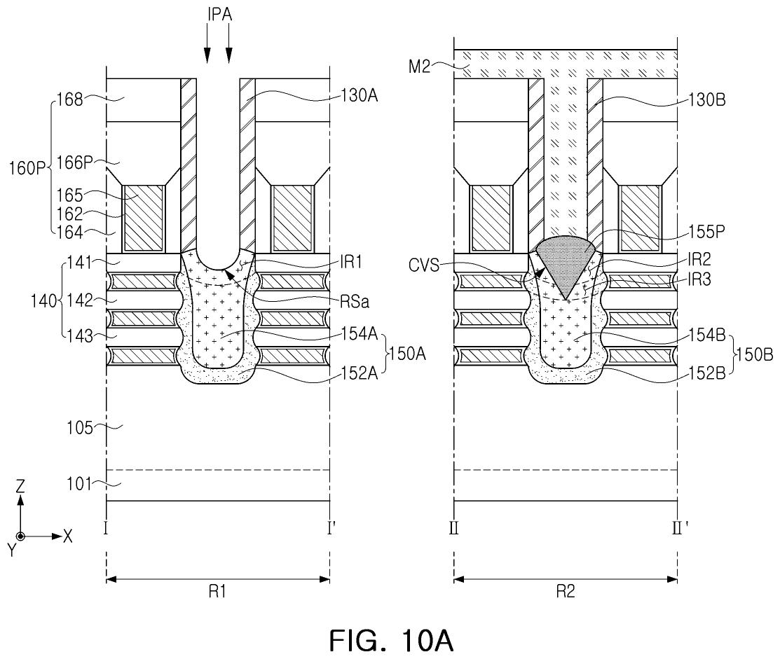

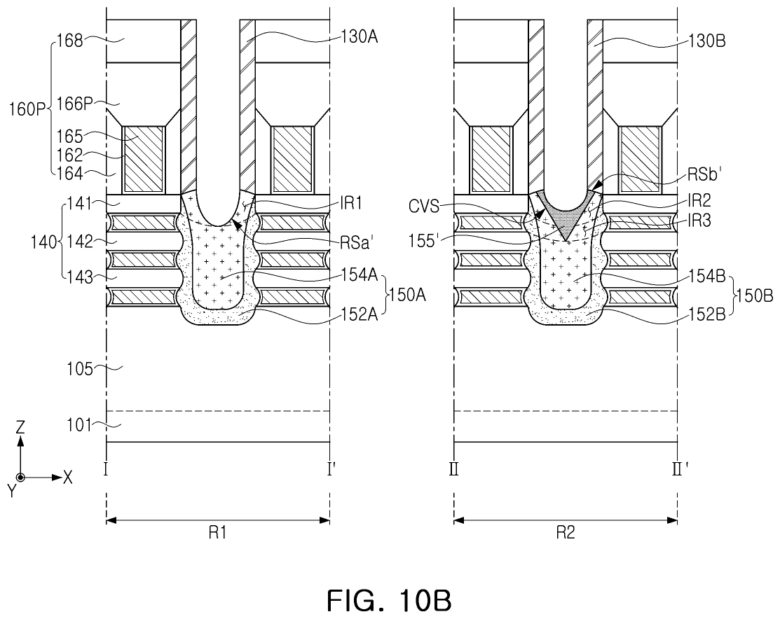

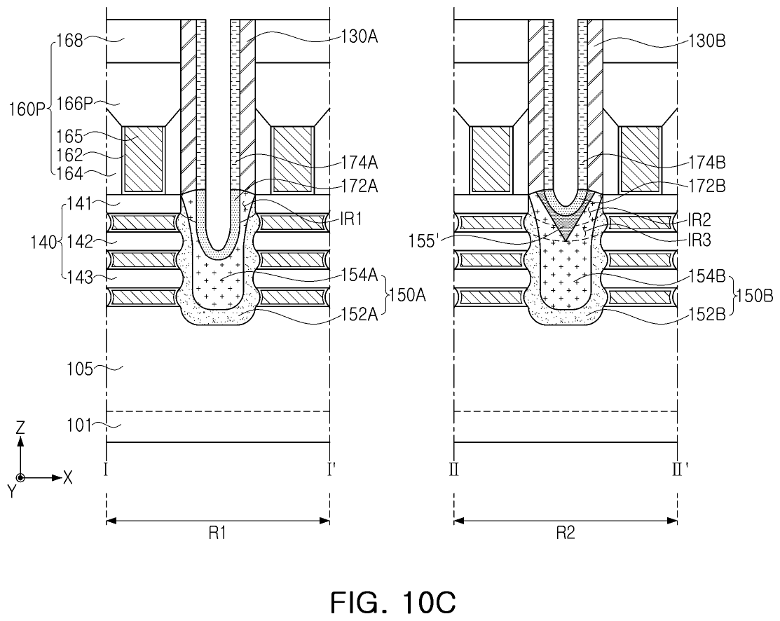

FIGS. 10A to 10C are cross-sectional views illustrating an embodiment of a method for manufacturing the semiconductor device in FIG. 5. The method for manufacturing the semiconductor device illustrated in FIGS. 10A to 10C may be subsequent processes performed after the process according to FIGS. 9A to 9F. That is, the processes illustrated in FIGS. 9A to 9F may be performed prior to the method for manufacturing the semiconductor device of FIG. 5.

Referring to FIG. 10A, after the process of forming the auxiliary epitaxial pattern 155, the first insulating liner 130A overlapping a first source/drain region 150A and the second gate capping layer 168 may be removed, and a second ion implantation process IPA may be performed to form a first impurity region IR1.

With the second mask pattern M2 covering the second region R2, the first insulating liner 130A overlapping the first source/drain region 150A may be removed through a first residue process for the first source/drain region 150A of the first region R1. The first residue process may be an anisotropic etching process, and may use an etching gas. Through the first residue process for the first source/drain region 150A, a portion of the second epitaxial layer 154A exposed through the first insulating liner 130A and an outer surface of the first source/drain region 150A may be removed. Silicon (Si) of the first source/drain region 150A may be removed, so that a first inner surface formed convexly toward the substrate 101 may be formed.

After performing the first residue process on the first source/drain region 150A, the second ion implantation process IPA may be performed on the first source/drain region 150A having the first inner surface exposed between the gate structures 160.

N-type impurities, such as at least one of phosphorus (P), arsenic (As) or antimony (Sb), may be implanted into the first source/drain region 150A exposed between the gate structures 160. The second ion implantation process IPA may be performed by an ion implant process.

Referring to FIG. 10B, a process of removing the second mask pattern M2 and a second residue process on the first source/drain region 150A of the first region R1 and the auxiliary epitaxial pattern 155P of the second region R2 of FIG. 10A may be performed.

Through the second residue process for the first source/drain region 150A of the first region R1, a portion of silicon (Si) exposed through the first inner surface of the second epitaxial layer 154A of the first source/drain region 150A may be removed to form a second inner surface formed convexly toward the substrate 101. A depth of the second inner surface may be greater than a depth of the first inner surface. The depth of the first inner surface may be a vertical length or distance from an upper surface of the channel structure 140 to a lower surface of the first inner surface, and a depth of the second inner surface may be a vertical length or distance from the upper surface of the channel structure 140 to a lower surface of the second inner surface.

Through the second residue process on the auxiliary epitaxial pattern 155 of the second region R2, silicon germanium (SiGe) of the auxiliary epitaxial pattern 155P exposed between the gate structures 160 may be removed to form the auxiliary epitaxial pattern 155′ having a third inner surface formed convexly toward the substrate 101. A depth of the third inner surface of the auxiliary epitaxial pattern 155′ may be less than the depth of the second inner surface of the first source/drain region 150A. The depth of the third inner surface may be a vertical length or distance from the upper surface of the channel structure 140 to a lower surface of the third inner surface.

Referring to FIG. 10C, the first metal-semiconductor compound layer 172A and the first conductive liner 174A recessing the second inner surface of the first source/drain region 150A may be formed, and the second metal-semiconductor compound layer 172B and the second conductive liner 174B recessing the third inner surface of the auxiliary epitaxial pattern 155′ may be formed.

A first protective layer (not shown) recessing the upper surface of the first source/drain region 150A may be deposited, and a heat treatment process may be sequentially performed, so that a portion of the first protective layer in contact with the second epitaxial layer 154A may react with the second epitaxial layer 154A. Accordingly, the first metal-semiconductor compound layer 172A may be formed on a portion of the first protective layer in contact with the second epitaxial layer 154A, and the first conductive liner 174A may be formed on the remaining portion that is not in contact with the second epitaxial layer 154A. In a process of forming a second protective layer (not shown), the auxiliary epitaxial pattern 155′ may have a fourth inner surface having a depth greater than that of the third inner surface of the auxiliary epitaxial pattern 155′, relative to the substrate 101. By depositing the second protective layer recessing the upper surface of the auxiliary epitaxial pattern 155′ and sequentially performing a heat treatment process, a portion of the second protective layer in contact with the auxiliary epitaxial pattern 155′ may react with the auxiliary epitaxial pattern 155′. Accordingly, the second metal-semiconductor compound layer 172B may be formed on the portion in contact with the auxiliary epitaxial pattern 155′, and the second conductive liner 174B may be formed in the remaining portion that is not in contact with the auxiliary epitaxial pattern 155′.

Next, referring to FIG. 3, FIG. 5 and FIG. 10C, the first conductive layer 176A may be formed on the first metal-semiconductor compound layer 172A and the first conductive liner 174A, and the second conductive layer 176B may be formed on the second metal-semiconductor compound layer 172B and the second conductive liner 174B. After forming the first conductive layer 176A and the second conductive layer 176B, a portion of the first gate capping layer 166P and the second gate capping layer 168 may be removed by a grinding and/or polishing process. In this way, the semiconductor device 100 of FIG. 5 may be manufactured.

The semiconductor device according to the embodiments of the present inventive concept may include an nFET region and a pFET region, and may include an auxiliary epitaxial pattern including a comparatively higher concentration of germanium between a source/drain region of a transistor in the pFET region and a contact structure. Accordingly, a contact resistance and a channel resistance of the transistor in the pFET region may be reduced, minimized and/or otherwise improved, thereby providing a semiconductor device having improved electrical characteristics.

However, effects of the present inventive concept are not limited to the effects described above, and may be expanded in various ways without departing from the scope of the present inventive concept.

While example embodiments have been shown and described above, it will be apparent to those skilled in the art that modifications and variations could be made without departing from the scope of the present inventive concept as defined by the appended claims.

What is claimed is:

1. A semiconductor device, comprising:
a substrate having a first region and a second region;
a first gate electrode extending on the first region in a first direction;
a second gate electrode extending on the second region in the first direction;
a plurality of channel layers spaced apart from each other in a second direction perpendicular to an upper surface of the substrate, the plurality of channel layers including first channel layers and second channel layers on the first region and the second region with the first gate electrode and the second gate electrode thereon, respectively;
a first source/drain region connected to the first channel layers on at least one side of the first gate electrode;
a second source/drain region connected to the second channel layers on at least one side of the second gate electrode;
an auxiliary epitaxial pattern extending into the second source/drain region from an upper surface thereof and electrically connected to the second source/drain region;
a first contact plug extending into the first source/drain region from an upper surface of the first source/drain region; and
a second contact plug extending into the auxiliary epitaxial pattern from an upper surface of the auxiliary epitaxial pattern,
wherein the first source/drain region has a first depth in the second direction from the upper surface of the first source/drain region and comprises a first impurity region including first impurities of a first conductivity type, and
the second source/drain region has a second depth in the second direction from the upper surface of the second source/drain region and comprises a second impurity region including second impurities of a second conductivity type that is different from the first conductivity type, the second depth being greater than the first depth.

2. The semiconductor device of claim 1, wherein the first contact plug extends into the first source/drain region to a third depth from the upper surface of the first source/drain region, and
the second contact plug extends into the second source/drain region to a fourth depth less than the third depth from the upper surface of the second source/drain region.

3. The semiconductor device of claim 1, wherein each of the first and second source/drain regions comprises:
a first epitaxial layer on side surfaces of the plurality of channel layers and having a first impurity concentration; and
a second epitaxial layer on the first epitaxial layer and having a second impurity concentration, greater than the first impurity concentration,
wherein an impurity concentration of the auxiliary epitaxial pattern is greater than the second impurity concentration.

4. The semiconductor device of claim 3, wherein an upper surface of the second epitaxial layer of the second source/drain region comprises:
a first portion; and
a second portion comprising a cavity extending from the first portion, wherein the auxiliary epitaxial pattern is in the cavity, and the first portion extends around the cavity.

5. The semiconductor device of claim 4, wherein an upper surface of the auxiliary epitaxial pattern is farther from the substrate than an upper surface of the first portion of the second epitaxial layer of the second source/drain region.

6. The semiconductor device of claim 3, further comprising:
a first metal-semiconductor compound layer extending into an upper surface of the second epitaxial layer of the first source/drain region and positioned between the second epitaxial layer and the first contact plug; and
a second metal-semiconductor compound layer extending into the upper surface of the auxiliary epitaxial pattern and positioned between the auxiliary epitaxial pattern and the second contact plug.

7. The semiconductor device of claim 1, wherein a bottom of the auxiliary epitaxial pattern is closer to the substrate than a lower boundary of the first impurity region.

8. The semiconductor device of claim 1, wherein the first impurities comprise at least one of phosphorus (P), arsenic (As), antimony (Sb), carbon (C) or argon (Ar).

9. The semiconductor device of claim 8, wherein the second impurities comprise at least one of boron (B), gallium (Ga) or aluminum (Al).

10. The semiconductor device of claim 1, wherein a lower boundary of the second impurity region is closer to the substrate than a lower surface of the second contact plug.

11. The semiconductor device of claim 1, wherein the first source/drain region is free of the auxiliary epitaxial pattern.

12. A semiconductor device, comprising:
a substrate comprising an active region extending in a first direction;
a gate structure extending in a second direction intersecting the active region on the substrate;
a plurality of channel layers on the active region and spaced apart from each other in a third direction, which is perpendicular to an upper surface of the substrate, with the gate structure thereon;
a source/drain region in a recessed region of the active region on at least one side of the gate structure and connected to the plurality of channel layers, wherein the source/drain region comprises a first epitaxial layer on the active region and in contact with the plurality of channel layers, and a second epitaxial layer on the first epitaxial layer, an upper surface of the second epitaxial layer comprising a first portion and a second portion having a cavity therein that extends toward the active region, the first portion extending around the cavity;
an auxiliary epitaxial pattern in the cavity of the second epitaxial layer and having a surface defined by a crystal plane;
a metal-semiconductor compound layer extending into an upper surface of the auxiliary epitaxial pattern, electrically connected to the source/drain region, and extending along a recessed surface of the auxiliary epitaxial pattern; and
a contact plug comprising a contact conductive layer on the metal-semiconductor compound layer, and extending in the third direction.

13. The semiconductor device of claim 12, wherein a portion of the auxiliary epitaxial pattern is farther from the substrate than an upper surface of the first portion of the second epitaxial layer.

14. The semiconductor device of claim 12, further comprising an insulating liner in contact with the second portion of the second epitaxial layer and extending along a side surface of the contact plug.

15. The semiconductor device of claim 14, further comprising a conductive liner extending from the metal-semiconductor compound layer and between the insulating liner and the contact plug.

16. The semiconductor device of claim 15, wherein the conductive liner is free of contact with the auxiliary epitaxial pattern.

17. The semiconductor device of claim 12, wherein the cavity comprises a first inclined plane, and the first inclined plane is a (1 1 1) crystal plane.

18. The semiconductor device of claim 12, further comprising an impurity region in the source/drain region and in contact with one or more of the plurality of channel layers, the impurity region having a first depth in the third direction from an upper surface of the source/drain region, and comprising impurities of a conductivity type,
wherein the impurity region contacts the auxiliary epitaxial pattern.

19. A semiconductor device, comprising:
a substrate having a first region and a second region;
a first gate electrode extending on the first region in a first direction;
a second gate electrode extending on the second region in the first direction;
a plurality of channel layers spaced apart from each other in a second direction perpendicular to an upper surface of the substrate, the channel layers comprising first channel layers and second channel layers on the first region and the second region and with the first gate electrode and the second gate electrode thereon, respectively;
a first source/drain region connected to the first channel layers on at least one side of the first gate electrode;
a second source/drain region connected to the second channel layers on at least one side of the second gate electrode;
an auxiliary epitaxial pattern extending into the second source/drain region from an upper surface thereof and electrically connected to the second source/drain region;
a first contact plug extending into the first source/drain region from an upper surface of the first source/drain region; and
a second contact plug extending into the auxiliary epitaxial pattern from an upper surface of the auxiliary epitaxial pattern,
wherein each of the first source/drain region and the second source/drain region comprises:
a first epitaxial layer on side surfaces of the plurality of channel layers and having a first impurity concentration; and
a second epitaxial layer on the first epitaxial layer and having a second impurity concentration, greater than the first impurity concentration, and
the semiconductor device further comprises:
a first metal-semiconductor compound layer extending into an upper surface of the second epitaxial layer in the first source/drain region and being in contact with the second epitaxial layer of the first source/drain region and the first contact plug; and
a second metal-semiconductor compound layer extending into the upper surface of the auxiliary epitaxial pattern and being in contact with the auxiliary epitaxial pattern and the second contact plug.

20. The semiconductor device of claim 19, wherein an impurity concentration of the auxiliary epitaxial pattern is greater than the second impurity concentration of the second epitaxial layer of the second source/drain region.
